(19) United States
(12) Patent Application Publication
(10) Pub. No.: US 2025/0268008 A1
(43) Pub. Date: Aug. 21, 2025

(54) WIRING SUBSTRATE AND MANUFACTURING METHOD THEREOF, ELECTRONIC DEVICE

(71) Applicants: Hefei BOE Ruisheng Technology Co., Ltd., Hefei, Anhui (CN); BOE Technology Group Co., Ltd., Beijing (CN)

(72) Inventors: Bing ZHANG, Beijing (CN); Liang GAO, Beijing (CN); Xiaoxiang ZHANG, Beijing (CN); Xiao WANG, Beijing (CN); Hai TANG, Beijing (CN); Jianwei QIN, Beijing (CN)

(21) Appl. No.: 18/702,474

(22) PCT Filed: Sep. 9, 2022
(86) PCT No.: PCT/CN2022/118096

§ 371 Date: Apr. 18, 2024

(51) Int. Cl. H10H 29/85; H10H 29/01; H10H 29/24

(52) U.S. Cl. CPC H10H 29/8508; H10H 29/0364; H10H 29/24; H10H 29/857

(57) ABSTRACT

The present disclosure provides a wiring substrate, a method manufacturing the same, and an electronic device. The wiring substrate includes a base substrate, a plurality of pad groups on the base substrate, each pad group including at least two pads. Two pads adjacent in a first direction or a second direction of the at least two pads are spaced apart. Each pad includes a plurality of sides including at least one selected side and at least one non-selected side, any one pad is adjacent to another pad along the first direction or the second direction, the selected side of the any one pad is a side facing the adjacent another pad, and a distance between the selected side of the any one pad facing the adjacent another pad and the selected side of the adjacent another pad facing the any one pad is ≥30 μm and <100 μm.

### RELATED APPLICATIONS

The present application is a 35 U.S.C. 371 national stage application of PCT International Application No. PCT/CN2022/118096 filed on Sep. 9, 2022, the entire disclosure of which is incorporated herein by reference.

### TECHNICAL FIELD

The present disclosure relates to the field of display technology, and in particular, to a wiring substrate, an electronic device comprising the wiring substrate, and a method of manufacturing the wiring substrate.

### BACKGROUND

The display devices generally comprise two categories: liquid crystal display devices and organic light-emitting diode display devices. Liquid crystal display devices are widely used due to their advantages such as thinness, lightness, good shock resistance, wide viewing angle, and high contrast. A liquid crystal display device generally comprises a display panel and a backlight, and the backlight is usually provided on the non-display side of the display panel to provide a light source for the display of the display panel. Characteristics such as contrast, brightness uniformity, and stability of a liquid crystal display device are related to the structure and performance of the backlight. In recent years, Mini light-emitting diode (Mini-LED) has attracted widespread attention due to its excellent performance and is increasingly used in the backlight.

### SUMMARY

According to an aspect of the present disclosure, a wiring substrate is provided, which comprises: a base substrate; a plurality of pad groups on the base substrate, each of the plurality of pad groups comprising at least two pads. Two pads adjacent in a first direction or a second direction of the at least two pads are spaced apart, the first direction intersects with the second direction, each of the at least two pads comprises a plurality of sides, the plurality of sides comprise at least one selected side and at least one non-selected side, any one pad is adjacent to another pad along the first direction or the second direction, the selected side of the any one pad is a side among the plurality of sides facing the adjacent another pad, and a distance between the selected side of the any one pad facing the adjacent another pad and the selected side of the adjacent another pad facing the any one pad is greater than or equal to 30 μm and less than 100 μm.

In some embodiments, the wiring substrate further comprises an insulating layer on a side of the plurality of pad groups away from the base substrate, the insulating layer comprises a plurality of first openings, any one of the plurality of first openings corresponds to one of the plurality of pad groups.

In some embodiments, any one of the plurality of pad groups comprises two pads spaced apart along the first direction or the second direction, an orthographic projection of the non-selected side of each of the two pads on the base substrate coincides with a part of a contour of an orthographic projection of a corresponding first opening on the base substrate.

In some embodiments, any one of the plurality of pad groups comprises four pads arranged in an array and spaced apart along the first direction and the second direction, the non-selected side of each of the four pads comprises at least one first non-selected side, and an orthographic projection of the first non-selected side on the base substrate coincides with a part of a contour of an orthographic projection of a corresponding first opening on the base substrate.

In some embodiments, the non-selected side of each pad further comprises a second non-selected side, and a minimum distance between an orthographic projection of the second non-selected side on the base substrate and the contour of the orthographic projection of the corresponding first opening on the base substrate is 30˜50 μm.

In some embodiments, any one of the plurality of pad groups comprises a plurality of pads spaced apart along the first direction or the second direction, a connection line sequentially connecting geometric centers of the plurality of pads in a clockwise direction forms a convex polygon, the non-selected side of each of the plurality of pads comprises at least one first non-selected side, and an orthographic projection of the first non-selected side on the base substrate coincides with a part of a contour of an orthographic projection of a corresponding first opening on the base substrate.

In some embodiments, the plurality of pads comprise a first type pad and a second type pad, the selected sides of the first type pad comprise a first selected side and a second selected side, an extending direction of the first selected side and an extending direction of the second selected side have an angle, the selected sides of the second type pad comprise a third selected side and a fourth selected side, and an extending direction of the third selected side is parallel to an extending direction of the fourth selected side.

In some embodiments, the first type pad is spaced apart from two second type pads in the first direction and the second direction respectively, and any pad adjacent to the second type pad is spaced apart from the second type pad along the first direction or the second direction.

In some embodiments, the non-selected sides of each first type pad further comprise a second non-selected side, and a minimum distance between an orthographic projection of the second non-selected side on the base substrate and the contour of the orthographic projection of the corresponding first opening on the base substrate is 30˜50 μm.

In some embodiments, the non-selected sides of each second type pad further comprise a third non-selected side, the second type pad is spaced apart from the first type pad along the first direction, a distance between the third non-selected side of the second type pad and the second selected side of the first type pad in the second direction is greater than zero and less than or equal to 30 μm, and the second selected side of the first type pad is a selected side of the first type pad facing the second type pad which is spaced apart from the first type pad along the second direction.

In some embodiments, the non-selected sides of each second type pad further comprise a third non-selected side, the second type pad is spaced apart from the first type pad along the second direction, a distance between the third non-selected side of the second type pad and the first selected side of the first type pad in the first direction is greater than zero and less than or equal to 30 μm, and the first selected side of the first type pad is a selected side of the first type pad facing the second type pad which is spaced apart from the first type pad along the first direction.

In some embodiments, no other layer is provided between a layer where the insulating layer is located and a layer where the plurality of pad groups are located.

According to another aspect of the present disclosure, an electronic device is provided, which comprises the wiring substrate described in any of the previous embodiments and a plurality of electronic elements. The plurality of electronic elements are on a side of the plurality of pad groups away from the base substrate, any one of the plurality of electronic elements corresponds to one of the plurality of pad groups, each of the plurality of electronic elements comprises at least two pins, any one of the at least two pins corresponds to one of the at least two pads, and each pin of an electronic element is connected to a corresponding pad.

In some embodiments, a ratio of an area of a surface of a pin of each electronic element facing the corresponding pad to an area of a surface of the corresponding pad facing the pin is 0.4˜1.0.

In some embodiments, a first orthographic projection of a pin of each electronic element on the base substrate at least partially overlaps with a second orthographic projection of the corresponding pad on the base substrate, a region where the first orthographic projection and the second orthographic projection overlap comprises an overlapping region, a ratio of an area of the overlapping region to an area of the second orthographic projection is greater than or equal to 39%.

In some embodiments, an insulating layer is between the plurality of pad groups and the plurality of electronic elements, any one of the plurality of electronic elements corresponds to one of a plurality of first openings of the insulating layer, a third orthographic projection of each electronic element on the base substrate falls within a fourth orthographic projection of a corresponding first opening on the base substrate, and a distance between a contour of the third orthographic projection and a contour of the fourth orthographic projection is 20˜40 μm.

According to yet another aspect of the present disclosure, a method of manufacturing an electronic device is provided, which comprises: providing a base substrate; forming a plurality of pad groups on the base substrate, each of the plurality of pad groups comprising at least two pads; and fixing a plurality of electronic elements on a side of the plurality of pad groups away from the base substrate. Any one of the plurality of electronic elements corresponds to one of the plurality of pad groups, each of the plurality of electronic elements comprises at least two pins, any one of the at least two pins corresponds to one of the at least two pads, and each pin of an electronic element is connected to a corresponding pad.

In some embodiments, the forming a plurality of pad groups on the base substrate, comprises: applying a conductive layer on the base substrate and patterning the conductive layer to form a plurality of signal lines; forming an insulating layer comprising a plurality of first openings on a side of the plurality of signal lines away from the base substrate, and forming the pads by exposing a portion of each of the plurality of signal lines by the first openings.

In some embodiments, the fixing a plurality of electronic elements on a side of the plurality of pad groups away from the base substrate, comprises: aligning each pin of the electronic element with the corresponding pad, so that a first orthographic projection of each pin of the electronic element on the base substrate does not exceed a second orthographic projection of the corresponding pad on the base substrate; and soldering each pin of the electronic element to the corresponding pad by a solder.

In some embodiments, each pad group comprises a plurality of pads spaced apart along a first direction or a second direction, the plurality of pads comprise a first type pad, the first type pad comprises a first selected side, a second selected side, a first non-selected side and a second non-selected side, an extending direction of the first selected side and an extending direction of the second selected side have an angle, and an extending direction of the first non-selected side and an extending direction of the second non-selected side have an angle. The aligning each pin of the electronic element with the corresponding pad, comprises: aligning the first selected side and the second selected side of each first type pad with a first side and a second side of a corresponding pin respectively in a direction perpendicular to the base substrate, and making orthographic projections of the first non-selected side and the second non-selected side of each first type pad on the base substrate spaced apart from orthographic projections of a third side and a fourth side of the corresponding pin on the base substrate respectively by 20˜50 μm.

In some embodiments, the plurality of pads further comprise a second type pad, the second type pad comprises a third selected side, a fourth selected side, a first non-selected side and a third non-selected side, an extending direction of the third selected side is parallel to an extending direction of the fourth selected side, and an extending direction of the first non-selected side is parallel to an extending direction of the third non-selected side. The aligning each pin of the electronic element with the corresponding pad, further comprises: aligning the third selected side and the fourth selected side of each second type pad with a fifth side and a sixth side of the corresponding pin respectively in the direction perpendicular to the base substrate, making an orthographic projection of the third non-selected side of each second type pad on the base substrate spaced apart from an orthographic projection of a seventh side of the corresponding pin on the base substrate by 0˜30 μm, and making an orthographic projection of the first non-selected side of each second type pad on the base substrate spaced apart from an orthographic projection of an eighth side of the corresponding pin on the base substrate by 20˜50 μm, the third non-selected side being closer to a center of a pad group than the first non-selected side.

In some embodiments, each pad group comprises a central region and a plurality of corner regions surrounding the central region, each of the plurality of corner regions is provided with at least one first type pad and at least one second type pad. Before aligning each pin of the electronic element with the corresponding pad, the method further comprises: placing a mesh on the side of the plurality of pad groups away from the base substrate, the mesh comprising a plurality of second openings, any one of the plurality of second openings corresponding to one of the plurality of corner regions of the plurality of pad groups, an orthographic projection of each of the plurality of second openings on the base substrate partially overlapping with orthographic projections of the at least one first type pad and the at least one second type pad in a corresponding corner region on the base substrate; printing soldering flux onto surfaces of the first type pad and the second type pad away from the base substrate through the second openings of the mesh; and removing the mesh.

### BRIEF DESCRIPTION OF THE DRAWINGS

In order to more clearly describe the technical solutions in the embodiments of the present disclosure, the accompanying drawings used in the embodiments will be briefly described. Obviously, the accompanying drawings in the following description are only some embodiments of the present disclosure. Those of ordinary skill in the art can also obtain other drawings based on these drawings without undue experimentation.

FIG. 1 illustrates a plan view of a light-emitting substrate in the related art;

FIG. 2 illustrates a plan view of a partial structure of a wiring substrate according to an embodiment of the present disclosure;

FIG. 3 illustrates another plan view of a partial structure of a wiring substrate according to an embodiment of the present disclosure;

FIG. 4 illustrates yet another plan view of a partial structure of a wiring substrate according to an embodiment of the present disclosure;

FIG. 5 illustrates still another plan view of a partial structure of a wiring substrate according to an embodiment of the present disclosure;

FIG. 6 illustrates the relative positional relationship between the pins of the electronic element and the pads soldered to the pins in the related art;

FIG. 7 illustrates a block diagram of an electronic device according to an embodiment of the present disclosure;

FIG. 8 illustrates a cross-sectional view of a partial structure of an electronic device according to an embodiment of the present disclosure;

FIG. 9 illustrates a plan view of a partial structure of an electronic device according to an embodiment of the present disclosure;

FIG. 10 illustrates another plan view of a partial structure of an electronic device according to an embodiment of the present disclosure;

FIG. 11 illustrates the relative positional relationship between the pins of the electronic element and the pads soldered to the pins according to an embodiment of the present disclosure;

FIG. 12 illustrates yet another plan view of a partial structure of an electronic device according to an embodiment of the present disclosure;

FIG. 13 illustrates a cross-sectional view of a partial structure of an electronic device according to an embodiment of the present disclosure;

FIG. 14 illustrates a flow chart of a method of manufacturing an electronic device according to an embodiment of the present disclosure;

FIG. 15 illustrates a structural diagram of a mesh used in the manufacturing process of the related art;

FIG. 16 illustrates another structural diagram of a mesh used in the manufacturing process of the related art;

FIG. 17 illustrates a structural diagram of a mesh used in a manufacturing process according to an embodiment of the present disclosure; and

FIG. 18 illustrates another structural diagram of a mesh used in a manufacturing process according to an embodiment of the present disclosure.

### DETAILED DESCRIPTION OF THE DISCLOSURE

The technical solutions in the embodiments of the present disclosure will be clearly described in the following with reference to the drawings. Apparently, the described embodiments are only some, but not all, of the embodiments of the present disclosure. Based on the embodiments in the present disclosure, all other embodiments obtained by those of ordinary skill in the art without undue experimentation belong to the protection scope of the present disclosure.

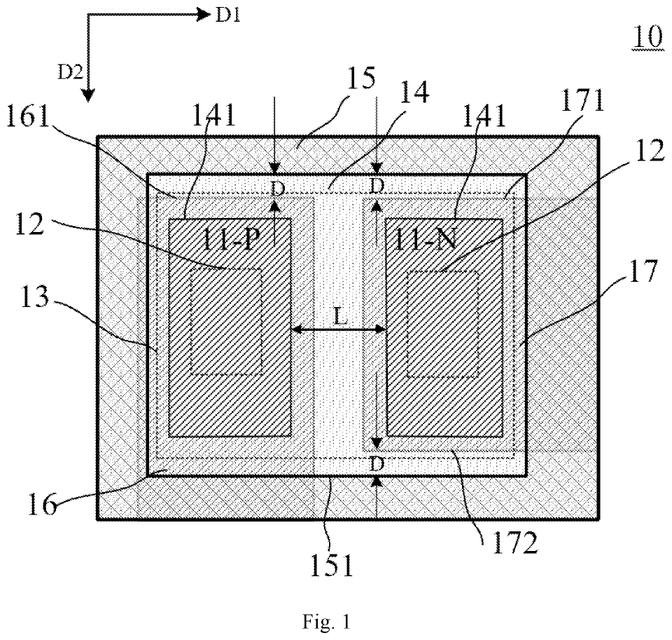

FIG. 1 illustrates a light-emitting substrate 10 in the related art. The light-emitting substrate 10 comprises signal lines 16 and 17, a first insulating layer 14 on the signal lines 16 and 17, a second insulating layer 15 on a side of the first insulating layer 14 away from the signal lines 16 and 17, and a light-emitting device 13 on a side of the second insulating layer 15 away from the first insulating layer 14. Each light-emitting device 13 comprises two pins 12 facing the second insulating layer 15. The first insulating layer 14 comprises an opening 141 at a position corresponding to each pin 12, the portion of the signal line 16 exposed by the opening 141 constitutes the pad 11-P, and the portion of the signal line 17 exposed by the opening 141 constitutes the pad 11-N. Except for the pads 11-P and 11-N, other portions of the signal lines 16 and 17 are covered by the first insulating layer 14, and the region between the two pads is covered by the first insulating layer 14. The pad 11-P and the corresponding pin 12 are connected to each other through solder, and the pad 11-N and the corresponding pin 12 are connected to each other through solder. In order to increase the soldering area between the pad and the pin 12, the edge of any one of the pad 11-P and the pad 11-N is expanded relative to the edge of the pin 12, that is, the orthographic projection of each pin 12 on the base substrate falls within the orthographic projection of a corresponding pad on the base substrate. Expanding the edges of the pads will cause the distance L between two adjacent pads to decrease, but because the first insulating layer 14 is between the two adjacent pads, the pin 12 that should be connected to the pad 11-P can be avoided from contacting with the adjacent pad 11-N to lead to a short circuit, that is, the pin 12 soldered to the pad 11-P does not contact with the pad 11-N. Similarly, the pin 12 soldered to the pad 11-N does not contact with the pad 11-P. The second insulating layer 15 comprises an opening 151 at a position corresponding to each light-emitting device 13. The orthographic projections of two pads 11-P and 11-N and the light-emitting device 13 on the base substrate all fall within the orthographic projection of the opening 151 on the base substrate.

The first insulating layer 14 maybe a single-layer structure or a multi-layer stacked structure. For example, the first insulating layer 14 may be a stacked structure of a passivation layer and an over coating (OC) layer. The material of the passivation layer is an inorganic material, such as SiN, SiO, or SiON, which can effectively block the intrusion of water and oxygen into the light-emitting substrate 10. The material of the OC layer is usually organic resin, which has good leveling properties and can be used as a planarization layer. The precision of the patterning process of the first insulating layer 14 is relatively high, and its precision is usually on the order of several microns. The material of the second insulating layer 15 may be white ink, white ink has a high reflectivity (for example, a reflectivity greater than 92%) and therefore is usually used as a reflective layer. Compared with the first insulating layer 14, the precision of the patterning process of the second insulating layer 15 is slightly lower, and its precision is usually above the order of hundreds of microns.

The inventor(s) of the present application found that the light-emitting substrate 10 comprises at least two insulating layers, which causes the light-emitting substrate 10 to be thicker, is not conducive to the thinning of the backplane, complicates the process, and increases the production cost. In order to reduce the thickness of the backplane and reduce the production cost, the second insulating layer 15 may be directly used to serve as both an insulating layer and a reflective layer. However, the inventor(s) of the present application found that, limited by the material of the second insulating layer 15 and the precision of the patterning process, the region between two adjacent pads is not provided with the insulating layer, instead, it is directly exposed by the opening 151 of the second insulating layer 15. If the related art is continued to be used, which evenly expands the edges of the pad, when the distance L between the two opposite sides of two adjacent pads is too small, since there is no first insulating layer 14, it is easy for the pin 12 soldered to one of the pads 11-P and 11-N to come into contact with the other of the pads 11-P and 11-N, resulting in a short circuit.

Therefore, a new pad design needs to be proposed to avoid short circuit problems.

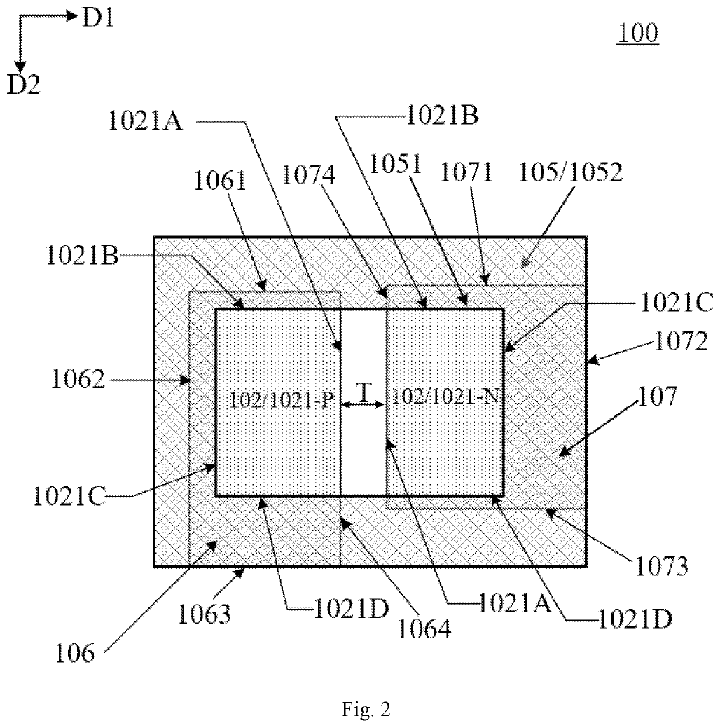

An embodiment of the present disclosure provides a wiring substrate 100, and the structure of the wiring substrate 100 may be described with reference to FIG. 2. The wiring substrate 100 comprises: a base substrate (not illustrated in the figure); and a plurality of pad groups 102 located on the base substrate, each pad group 102 comprising at least two pads. Two pads adjacent in a first direction D1 or a second direction D2 of the at least two pads are spaced apart, the first direction D1 intersects with the second direction D2, for example, the first direction D1 may be perpendicular to the second direction D2. Each pad comprises a plurality of sides, the plurality of sides comprise at least one selected side 1021A and at least one non-selected side 1021B, any one pad is adjacent to another pad along the first direction D1 or the second direction D2, the selected side 1021A of any one pad is the side among the plurality of sides facing the adjacent another pad, and a distance T between the selected side 1021A of any one pad facing the adjacent another pad and the selected side 1021A of the adjacent another pad facing the any one pad is greater than or equal to 30 μm and less than 100 μm. For example, T may be 30 μm, 50 μm, 65 μm, 90 μm, 99 μm, etc. The distance T is less than the value in the related art. In the related art, the distance between two opposite sides of two adjacent pads is greater than 100 μm.

It should be pointed out that during the manufacturing process, solder needs to be coated to the surface of the pad for soldering to the pin, and the lower limit of the distance T is associated with the accuracy of the solder coating. For example, if the accuracy of solder coating is ±30 μm, the lower limit of T is 30 μm; if the accuracy of solder coating is ±50 μm, the lower limit of T is 50 μm. The accuracy of solder coating is related to the size of the wiring substrate, for example, the accuracy of solder coating of a 32-inch wiring substrate may reach ±50 μm, and the accuracy of solder coating of a 16-inch wiring substrate may reach ±30 μm.

The pad groups comprising different numbers of pads will be described below by several different embodiments.

FIG. 2 illustrates an example of the pad group 102 of the wiring substrate 100. In the example, each pad group 102 comprises two pads 1021-P and 1021-N, the two pads 1021-P and 1021-N are respectively connected to two pins of the light-emitting element. Specifically, the two pads are spaced apart along the first direction D1. Each of the two pads 1021-P and 1021-N comprises four sides that respectively are a selected side 1021A and non-selected sides 1021B, 1021C and 1021D, that is, each pad comprises one selected side and three non-selected sides. As defined previously, the “selected side” needs to meet the following two conditions: first, the selected side faces the other adjacent pad, and second, the distance T between the selected side and the selected side of the other adjacent pad needs to be greater than or equal to 30 μm and less than 100 μm. Correspondingly, if there is no the other pad within 100 μm of a side of the pad in the first direction D1 or the second direction D2, then the side is the non-selected side of the pad. In the example of FIG. 2, the side 1021A of the pad 1021-P is the selected side, because the side 1021A faces the other adjacent pad 1021-N, and the distance T between this side 1021A and the side 1021A of the other adjacent pad 1021-N is greater than or equal to 30 μm and less than 100 μm. Sides 1021B, 1021C and 1021D of the pad 1021-P are non-selected sides, because there is no other pad within 100 μm of the side 1021C in the first direction D1 (the distance between the side 1021A of the pad 1021-N and the non-selected side 1021C of the pad 1021-P is greater than 100 μm), and there is no other pad within 100 μm of the sides 1021B and 1021D in the second direction D2. Similarly, the side 1021A of the pad 1021-N is the selected side, and sides 1021B, 1021C, and 1021D of the pad 1021-N are non-selected sides. The distance T between the selected side 1021A of the pad 1021-P and the selected side 1021A of the pad 1021-N is greater than or equal to 30 μm and less than 100 μm. For example, the distance T may be 30 μm, 50 μm, 65 μm, 90 μm, 99 μm, etc.

It should be noted that although the four sides of each pad are illustrated as straight lines in FIG. 2, this is only a schematic embodiment. In an alternative embodiment, the four sides of each pad may also be folded segments or curved segments with their tails connected in turn. In another alternative embodiment, some of the four sides of each pad may be straight lines, and the remaining sides may be folded segments or curved segments with their tails connected in turn. It can be understood that when a side is composed of multiple folded segments or curved segments with their tails connected in turn, the angle between two adjacent folded segments shall not be greater than 30°, and the angle between the tangent directions of two adjacent curved segments is not greater than 30°. When a side is composed of multiple folded segments or curved segments with their tails connected in turn, the extending direction of the side is the direction of the line connecting the two endpoints of the side. It should be noted that, for simplicity, only one pad group 102 is illustrated in FIG. 2, and other plurality of pad groups 102 are not illustrated.

As illustrated in FIG. 2, the wiring substrate 100 also comprises an insulating layer 105 located on a side of the pad group 102 away from the base substrate. The insulating layer 105 comprises a plurality of first openings 1051, and any one of the plurality of first openings 1051 corresponds to one of the plurality of pad groups 102. The material of the insulating layer 105 may be, for example, white ink. White ink has a high reflectivity, for example, a reflectivity greater than 92%, and therefore has a reflective effect on the light emitted by the light-emitting element. There is no other intermediate layer between the layer where the insulating layer 105 is located and the layer where the multiple pad groups 102 are located, that is, the insulating layer 105 is in direct contact with the signal line where the pads are located.

The wiring substrate 100 also comprises a plurality of signal lines located on the same layer as the plurality of pad groups 102. The portion of each signal line exposed by the first opening 1051 constitutes the pad 1021-P or 1021-N as described above, that is, each pad is a portion of a corresponding signal line. FIG. 2 illustrates two signal lines 106 and 107. The portion of the signal line 106 exposed by the first opening 1051 is used as the pad 1021-P, and the portion of the signal line 107 exposed by the first opening 1051 is used as the pad 1021-N. That is to say, the portion of the signal line 106 overlapping with the first opening 1051 defines the size of the pad 1021-P and the position of the four sides, and the portion of the signal line 107 overlapping with the first opening 1051 defines the size of the pad 1021-N and the position of the four sides. As illustrates in FIG. 2, the orthographic projections of the non-selected sides 1021B, 1021C, and 1021D of each pad on the base substrate coincide with the partial contour of the orthographic projection of the first opening 1051 on the base substrate. The signal line 106 also comprises other portions covered by the insulating layer 105, which are mainly used for transmitting electrical signals. The signal line 107 also comprises other portions covered by the insulation layer 105, which are mainly used for transmitting electrical signals. The orthographic projection of other portion of the signal line 106 except the pad 1021-P and the orthographic projection of other portion of the signal line 107 except the pad 1021-N on the base substrate fall within the orthographic projection of the body portion 1052 of the insulating layer 105 on the base substrate. The “body portion 1052” here refers to the portion of the insulating layer 105 except the first opening 1051.

Referring to FIG. 1, in the related art, the orthographic projection of the side 161 of the signal line 16 on the base substrate and the partial contour of the orthographic projection of the opening 151 of the second insulating layer 15 on the base substrate have a distance D, and the orthographic projection of the side 161 of the signal line 16 on the base substrate falls within the orthographic projection of the first insulating layer 14 on the base substrate. The orthographic projections of the sides 171 and 172 of the signal line 17 on the base substrate and the partial contour of the orthographic projection of the opening 151 of the second insulating layer 15 on the base substrate respectively have a distance D, and the orthographic projections of the sides 171 and 172 of the signal line 17 on the base substrate fall within the orthographic projection of the first insulating layer 14 on the base substrate. That is to say, although the orthographic projection of the side 161 of the signal line 16 on the base substrate falls within the orthographic projection of the opening 151 on the base substrate, the side 161 may be covered by the first insulating layer 14 located between the signal line 16 and the second insulating layer 15. Similarly, although the orthographic projections of the sides 171 and 172 of the signal line 17 on the base substrate fall within the orthographic projection of the opening 151 on the base substrate, the sides 171 and 172 may be covered by the first insulating layer 14 located between the signal line 17 and the second insulating layer 15. Therefore, the first insulating layer 14 can prevent water, oxygen, etc. in the environment from intruding into the light-emitting substrate 10 along the sides of the signal lines 16 and 17.

However, if it is necessary to make the wiring substrate 100 thinner and reduce the production cost, the first insulating layer 14 is not provided. If the design regarding the relative positional relationship between the signal lines 16 and 17 and the second insulating layer 15 in the related art is still used, the side 161 of the signal line 16 and the sides 171 and 172 of the signal line 17 will be directly exposed by the opening 151 of the second insulating layer 15. As a result, water and oxygen in the environment will intrude into the interior of the wiring substrate along the sides of the signal lines, corrode the signal lines, thereby affecting the electrical performance of the signal lines. In order to at least solve this technical problem, the inventor(s) of the present application improves the relative positional relationship between the first opening 1051 of the insulating layer 105 and the signal lines 106 and 107. Specifically, as shown in FIG. 2, the signal line 106 is, for example, a strip structure, which comprises four sides 1061, 1062, 1063, and 1064, at least the orthographic projections of the sides 1061, 1062, and 1063 on the base substrate fall within the orthographic projection of the body portion 1052 of the insulating layer 105 on the base substrate, that is, the sides 1061, 1062, and 1063 are covered by the body portion 1052 of the insulating layer 105. Similarly, the signal line 107 is, for example, a strip structure, which comprises four sides 1071, 1072, 1073 and 1074, at least the orthographic projections of the sides 1071, 1072, and 1073 on the base substrate fall within the orthographic projection of the body portion 1052 of the insulating layer 105 on the base substrate, that is, the sides 1071, 1072, and 1073 are covered by the body portion 1052 of the insulating layer 105. By covering most of the sides of the signal lines 106 and 107 with the body portion 1052 of the insulating layer 105, water, oxygen, etc. in the environment can be effectively prevented from intruding into the interior of the wiring substrate 100 along the sides of the signal lines 106 and 107, preventing the signal lines 106 and 107 from being corroded.

In the example of FIG. 2, the arrangement of the pads 1021-P and 1021-N is optimized so that the distance T between two opposite selected sides 1021A of two adjacent pads is greater than or equal to 30 μm and less than 100 μm. The setting of the value of the distance T provides a reasonable space for subsequent soldering with the pin of the electronic element. On the premise that there is no insulating layer covering between two adjacent pads, on the one hand, the distance T can ensure that the pin will not come into contact with other pads that should not have an electrical connection with the pin, so as to avoid a short circuit, for example, a pin connected to the pad 1021-P will not come into contact with the pad 1021-N, and a pin connected to the pad 1021-N will not come into contact with the pad 1021-P; on the other hand, the distance T can also maximize the area of the surfaces of the pads 1021-P and 1021-N facing the pins of the electronic element on the basis of avoiding short circuit, which increases the soldering area between the pads 1021-P and 1021-N and the pins, and reduces or even avoids soldering defects such as weak soldering due to insufficient contact area.

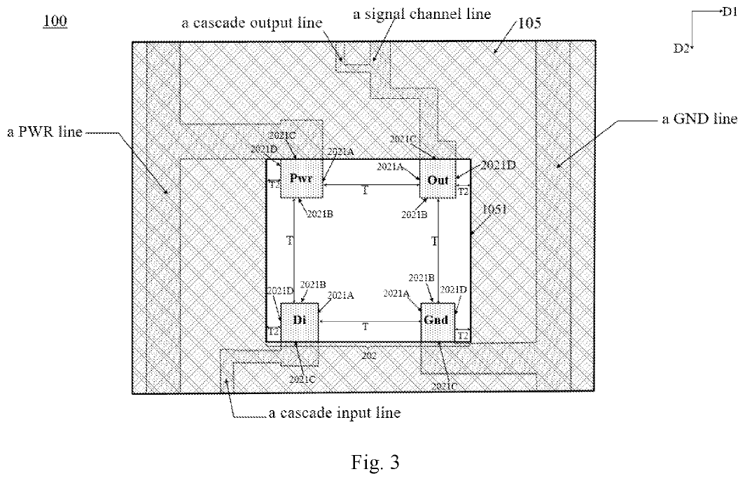

FIG. 3 illustrates another example of the pad group 202 of the wiring substrate 100, in this example, each pad group 202 comprises four pads arranged in an array and spaced apart along the first direction D1 and the second direction D2. The four pads are configured to be connected to four pins of the driver chip respectively, that is, the pad group 202 is used to connect to the driver chip with four pins. Specifically, as illustrated in FIG. 3, the wiring substrate 100 also comprises signal lines such as a PWR line, a cascade output line, a cascade input line, a GND line, and a signal channel line. The portion of the PWR line exposed by the first opening 1051 of the insulating layer 105 is used as the pad Pwr, and the pad Pwr is connected to the power pin pwr of the driver chip, therefore, the power supply voltage signal on the PWR line can be transmitted to the power pin pwr via the pad Pwr. The portion of the GND line exposed by the first opening 1051 of the insulating layer 105 is used as the pad Gnd, and the pad Gnd is connected to the ground pin gnd of the driver chip, therefore, the ground signal on the GND line can be transmitted to the ground pin gnd via the pad Gnd. One end of the signal channel line exposed by the first opening 1051 of the insulating layer 105 is used as the pad Out, the pad Out is connected to the output pin out of the driver chip, and the other end of the signal channel line is connected to the light-emitting element. The branch of the signal channel line is also connected to the cascade output line, which is connected to the pad Di of the next cascaded pad group. The pad Di of the next cascaded pad group is connected to the address pin di of the next cascaded driver chip. Therefore, the output pin out is a multiplexed pin, which outputs a driving signal within a period of time and transmits the driving signal to the light-emitting element through the signal channel line, so that the light-emitting element emits light; and outputs a relay signal in another period of time and transmits the relay signal to the address pin di of the next cascaded driver chip cascaded with the driver chip via the signal channel line and the cascade output line, so that the relay signal is used as the address signal of the next cascaded driver chip. The portion of the cascade input line exposed by the first opening 1051 of the insulating layer 105 is used as the pad Di, and the pad Di is connected to the address pin di of the driver chip. The cascade input line is usually connected to the previous cascade pad Out to receive the relay signal transmitted by the previous cascade output pin out, and the relay signal is transmitted to the address pin di of the driver chip as the address signal of the driver chip.

As illustrated in FIG. 3, each pad group 202 comprises four pads Pwr, Out, Di, and Gnd, and each of the four pads includes four sides, namely selected sides 2021A and 2021B and non-selected sides 2021C and 2021D respectively, that is, each pad comprises two selected sides and two non-selected sides. Taking the pad Pwr as an example, the selected side 2021A of the pad Pwr faces the pad Out adjacent in the first direction D1, and the distance T between the selected side 2021A of the pad Pwr and the selected side 2021A of the pad Out is greater than or equal to 30 μm and less than 100 μm. The selected side 2021B of the pad Pwr faces the pad Di adjacent in the second direction D2, and the distance T between the selected side 2021B of the pad Pwr and the selected side 2021B of the pad Di is greater than or equal to 30 μm and less than 100 μm. There is no other pad within 100 μm of the non-selected side 2021C of the pad Pwr in the second direction D2, For example, the distance between the selected side 2021B of the pad Di adjacent to the pad Pwr in the second direction D2 and the non-selected side 2021C of the pad Pwr is greater than 100 μm. There is no other pad within 100 μm of the non-selected side 2021D of the pad Pwr in the first direction D1, for example, the distance between the selected side 2021A of the pad Out adjacent to the pad Pwr in the first direction D1 and the non-selected side 2021D of the pad Pwr is greater than 100 μm. At least one of the non-selected sides 2021C and 2021D is a first non-selected side, and the orthographic projection of the first non-selected side on the base substrate coincides with a partial contour of the orthographic projection of the first opening 1051 on the base substrate. In the example of FIG. 3, the non-selected side 2021C is the first non-selected side, and the orthographic projection of the non-selected side 2021C on the base substrate coincides with a partial contour of the orthographic projection of the first opening 1051 on the base substrate. The non-selected side 2021D is a second non-selected side, and the minimum distance between the orthographic projection of the second non-selected side on the base substrate and the contour of the orthographic projection of the first opening 1051 on the base substrate is T2, T2 is 30˜50 μm, for example, T2 may be 30 μm, 40 μm, 50 μm, etc. In an alternative embodiment, the non-selected sides 2021C and 2021D may both be the first non-selected sides, and their orthographic projections on the base substrate respectively coincide with the partial contour of the orthographic projection of the first opening 1051 on the base substrate. In this case, there is no second non-selected side among the non-selected sides of the pad.

In the example of FIG. 3, the arrangement of the pads is optimized so that the distance T between two opposite selected sides 2021A or 2021B of two adjacent pads is greater than or equal to 30 μm and less than 100 μm. The setting of the value of the distance T provides a reasonable space for subsequent soldering with the pin of the electronic element. On the premise that there is no insulating layer covering between two adjacent pads, on the one hand, the distance T can ensure that the pin will not come into contact with other pads that should not have an electrical connection with the pin, so as to avoid a short circuit; on the other hand, the distance T can also maximize the area of the surface of the pad facing the pin of the electronic element on the basis of avoiding short circuit, which increases the soldering area between the pad and the pin, and reduces or even avoids soldering defects such as weak soldering due to insufficient contact area.

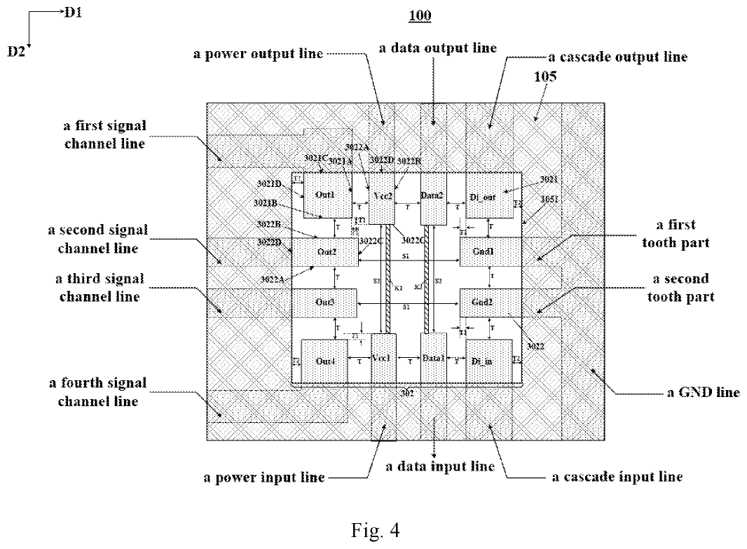

FIG. 4 illustrates yet another example of the pad groups 302 of the wiring substrate 100. In this example, each pad group 302 comprises twelve pads spaced apart along the first direction D1 or the second direction D2. The twelve pads are configured to be respectively connected to the twelve pins of the driver chip, that is, the pad group 302 is used for a driver chip with twelve pins. Specifically, as illustrated in FIG. 4, the wiring substrate 100 also comprises signal lines such as a power output line, a data output line, a power input line, a data input line, a cascade input line, a cascade output line, a GND line (comprising a first tooth part, a second tooth part), a first signal channel line, a second signal channel line, a third signal channel line and a fourth signal channel line. The portion of the power input line exposed by the first opening 1051 of the insulating layer 105 is used as a pad Vcc1, the pad Vcc1 is connected to the power pin vcc1 of the driver chip, therefore, the power voltage signal on the power input line can be transmitted to the power pin vcc1 via the pad Vcc1. The portion of the power output line exposed by the first opening 1051 of the insulating layer 105 is used as a pad Vcc2, the pad Vcc2 is connected to the power pin vcc2 of the driver chip, and the power output line is usually connected to the pad Vcc1 of the next cascaded pad group 302. The pads Vcc1 and Vcc2 are connected to each other via the connection line K1, so the power pins vcc1 and vcc2 of the driver chip receive the same voltage signal, and the power pin vcc2 can output a power signal to the power pin vcc1 of the next cascaded driver chip through the power output line. It can be understood that the power output line and the power input line are two relative concepts, which are named according to the signal flow direction of the power lines respectively connected to two power pins vcc1 and vcc2 of the same driver chip. That is, the power input line connected to the power pin vcc1 of the current driver chip is also the power output line connected to the power pin vcc2 of the previous cascade driver chip, the power output line connected to the power pin vcc2 of the current driver chip is also the power input line connected to the power pin vcc1 of the next cascade driver chip. The portion of the data input line exposed by the first opening 1051 of the insulating layer 105 is used as a pad Data1, the pad Data1 is connected to the data pin data1 of the driver chip, so the driving signal on the data input line can be transmitted to the data pin data1 via the pad Data1. The portion of the data output line exposed by the first opening 1051 of the insulating layer 105 is used as a pad Data2, the pad Data2 is connected to the data pin data2 of the driver chip, and the data output line is usually connected to the pad Data1 of the next cascade pad group 302. The pads Data1 and Data2 are connected to each other via the connection line K2, so the data pins data1 and data2 of the driver chip receive the same drive signal, and the data pin data2 can transmit the driving signal to the data pin data1 of the next cascade driver chip through the data output line. It can be understood that the data output line and the data input line are two relative concepts, which are named according to the signal flow direction of the signal lines respectively connected to the two data pins data1 and data2 of the same driver chip. That is, the data input line connected to the data pin data1 of the current driver chip is also the data output line connected to the data pin data2 of the previous cascade driver chip, the data output line connected to the data pin data2 of the current driver chip is also the data input line connected to the data pin data1 of the next cascade driver chip. The portion of the first tooth part of the GND line exposed by the first opening 1051 of the insulating layer 105 is used as a pad Gnd1, and the pad Gnd1 is connected to the ground pin gnd1 of the driver chip. The portion of the second tooth part of the GND line exposed by the first opening 1051 of the insulating layer 105 is used as a pad Gnd2, and the pad Gnd2 is connected to the ground pin gnd2 of the driver chip. Both the first tooth part of the GND line and the second tooth part of the GND line are connected to the main part of the GND line, and the main part has an angle with the extending direction of the first tooth part and/or the second tooth part. Therefore, the signal transmitted by the GND line can be transmitted to the ground pins gnd1 and gnd2 via the first tooth part and the second tooth part respectively. The portion of the cascade input line exposed by the first opening 1051 of the insulating layer 105 is used as a pad Di_in, and the pad Di_in is connected to the address pin di_in of the driver chip. The cascade input line is usually connected to the previous cascade pad Di_out to receive the relay signal transmitted by the previous cascade relay pin di_out, and the relay signal is transmitted to the address pin di_in of the driver chip to be used as the address signal of the driver chip. The portion of the cascade output line exposed by the first opening 1051 of the insulating layer 105 is used as a pad Di_out, and the pad Di_out is connected to the relay pin di_out of the driver chip. The cascade output line is connected to the pad Di_in of the next cascaded pad group, and the relay signal is transmitted by the relay pin di_out to the address pin di_in of the next cascaded driver chip cascaded with the driver chip via the cascade output line to serve as the address signal of the next cascaded driver chip. One ends of the first signal channel line, the second signal channel line, the third signal channel line and the fourth signal channel line exposed by the first opening 1051 of the insulating layer 105 are respectively used as pads Out1, Out2, Out3 and Out4, and the other ends of the first signal channel line, the second signal channel line, the third signal channel line and the fourth signal channel line are connected to four light-emitting elements. The pads Out1˜Out4 are connected to the output pins out1˜out4 of the driver chip respectively, thus, one driver chip can simultaneously control at least four light-emitting elements to emit light.

It should be noted that although FIG. 4 illustrates the arrangement positions of twelve pads, this is only an example, and the position of each pad of the pad group 302 needs to adapt to the position of each pin of the driver chip. When the position of the pin of the driver chip changes, the position of the pad of the pad group 302 also needs to be changed accordingly.

As illustrated in FIG. 4, a connection line sequentially connecting geometric centers of the twelve pads in a clockwise direction forms a convex polygon. The definition of “convex polygon” in the textbook is: any one of all sides of a polygon is infinitely extended to two directions to form a straight line, if all the remaining sides are on the same side of this straight line, the polygon is a convex polygon. The twelve pads comprise a first type pad and a second type pad. The number of the first type pads is 4, which are pads Out1, Out4, Di_out, and Di_in, and this application uses the reference numeral 3021 to denote the first type pad. The number of the second type pads is 8, which are Out2, Out3, Gnd1, Gnd2, Vcc1, Vcc2, Data1, and Data2, and this application uses the reference numeral 3022 to denote the second type pad. Two second type pads 3022 are arranged between two adjacent first type pads 3021.

Each first type pad 3021 comprises four sides, which are selected sides 3021A and 3021B and non-selected sides 3021C and 3021D respectively. That is, each first type pad 3021 comprises two selected sides and two non-selected sides. Taking the first type pad Out1 in FIG. 4 as an example, the selected side 3021A of the first type pad Out1 faces the second type pad Vcc2 adjacent in the first direction D1, and the distance T between the selected side 3021A of the first type pad Out1 and the selected side 3022A of the second type pad Vcc2 is greater than or equal to 30 μm and less than 100 μm. The selected side 3021B of the first type pad Out1 faces the second type pad Out2 adjacent in the second direction D2, and the distance T between the selected side 3021B of the first type pad Out1 and the selected side 3022B of the second type pad Out2 is greater than or equal to 30 μm and less than 100 μm. The selected side 3021A of the first type pad Out1 may be referred to as the first selected side, and the selected side 3021B of the first type pad Out1 may be referred to as the second selected side. The extending directions of the first selected side and the second selected side have an angle. For example, the angle may be any angle greater than 0 degrees and less than 180 degrees. There is no other pad within 100 μm of the non-selected side 3021C of the first type pad Out1 in the second direction D2, for example, the distance between the selected side 3022B of the second type pad Out2 that is adjacent to the first type pad Out1 in the second direction D2 and the non-selected side 3021C of the first type pad Out1 is greater than 100 μm. There is no other pad within 100 μm of the non-selected side 3021D of the first type pad Out1 in the first direction D1, for example, the distance between the selected side 3022A of the second type pad Vcc2 that is adjacent to the first type pad Out1 in the first direction D1 and the non-selected side 3021D of the first type pad Out1 is greater than 100 μm.

At least one of the non-selected sides 3021C and 3021D is a first non-selected side, and the orthographic projection of the first non-selected side on the base substrate coincides with a partial contour of the orthographic projection of the first opening 1051 on the base substrate. In the example of FIG. 4, the non-selected side 3021C is the first non-selected side, and the orthographic projection of the non-selected side 3021C on the base substrate coincides with the partial contour of the orthographic projection of the first opening 1051 on the base substrate. The non-selected side 3021D is a second non-selected side, and the minimum distance between the orthographic projection of the second non-selected side on the base substrate and the contour of the orthographic projection of the first opening 1051 on the base substrate is T2, T2 is 30˜50 μm, for example, it may be 30 μm, 40 μm, 50 μm, etc. In an alternative embodiment, the non-selected sides 3021C and 3021D may both be first non-selected sides, their orthographic projections on the base substrate respectively coincide with the partial contour of the orthographic projection of the first opening 1051 on the base substrate. In this case, there is no second non-selected side among the non-selected sides of the first type pad 3021.

The arrangement of the four sides of any of the other three first type pads is the same as the arrangement of the four sides of the first type pad Out1 described above, and will not be described again here for the sake of brevity.

Eight second type pads 3022 may be divided into two categories. One type is the second type pads 3022 which are spaced apart from the first type pad 3021 along the first direction D1, such as pads Vcc1, Vcc2, Data1, and Data2, the other type is the second type pads 3022 which are spaced apart from the first type pad 3021 along the second direction D2, such as pads Out2, Out3, Gnd1, and Gnd2. Any of the eight second type pads 3022 comprises four sides, which are selected sides 3022A and 3022B and non-selected sides 3022C and 3022D, respectively. That is, each second type pad 3022 comprises two selected sides and two non-selected sides. Taking the second type pad Out2 in FIG. 4 as an example, the selected side 3022A of the second type pad Out2 faces the second type pad Out3 adjacent in the second direction D2, and the distance T between the selected side 3022A of the second type pad Out2 and the selected side 3022B of the second type pad Out3 is greater than or equal to 30 μm and less than 100 μm. The selected side 3022B of the second type pad Out2 faces the first type pad Out1 adjacent in the second direction D2, and the distance T between the selected side 3022B of the second type pad Out2 and the selected side 3021B of the first type pad Out1 is greater than or equal to 30 μm and less than 100 μm. The selected side 3022A of the second type pad Out2 may be referred to as the third selected side, and the selected side 3022B of the second type pad Out2 may be referred to as the fourth selected side. The extending direction of the third selected side is parallel to the extending direction of the fourth selected side. Although the second type pad Out2 has an adjacent second type pad Gnd1 in the first direction D1, since the distance S1 in the first direction D1 between the side 3022C of the second type pad Out2 and the side of the adjacent second type pad Gnd1 is greater than 100 μm, the side 3022C of the second type pad Out2 is the non-selected side. Similarly, the side 3022D of the second type pad Out2 is also the non-selected side. Similarly, for the second type pads 3022 spaced apart from the first type pad 3021 along the first direction D1, their selected sides are 3022A and 3022B, and their non-selected sides are 3022C and 3022D. Taking the second type pad Vcc2 as an example, although the second type pad Vcc2 has an adjacent second type pad Vcc1 in the second direction D2, since the distance S2 in the second direction D2 between the side 3022C of the second type pad Vcc2 and the side of the adjacent second type pad Vcc1 is greater than 100 μm, the side 3022C of the second type pad Vcc2 is the non-selected side. Similarly, the side 3022D of the second type pad Vcc2 is also the non-selected side.

The non-selected side 3022D is the first non-selected side, and the orthographic projection of the first non-selected side on the base substrate coincides with the partial contour of the orthographic projection of the first opening 1051 on the base substrate. The non-selected side 3022C is the third non-selected side. For the second type pads 3022 which are spaced apart from the first type pad 3021 along the first direction D1, taking the second type pad Vcc2 as an example, the distance T1 in the second direction D2 between the third non-selected side 3022C of the second type pad Vcc2 and the second selected side 3021B of the first type pad Out1 is greater than 0 and less than or equal to 30 μm, the distance T1 may be, for example, 5 μm, 10 μm, 15 μm, 20 μm, 25 μm, 30 μm, etc. The second selected side 3021B is the selected side of the first type pad Out1 facing the second type pad Out2. For the second type pads 3022 which are spaced apart from the first type pad 3021 along the second direction D2, taking the second type pad Out2 as an example, the distance T1 in the first direction D1 between the third non-selected side 3022C of the second type pad Out2 and the first selected side 3021A of the first type pad Out1 is greater than 0 and less than or equal to 30 μm, the distance T1 may be, for example, 5 μm, 10 μm, 15 μm, 20 μm, 25 μm, 30 μm, etc. The first selected side 3021A is the selected side of the first type pad Out1 facing the second type pad Vcc2.

As illustrated in FIG. 4, there are two second type pads 3022 near each first type pad 3021, and the distance T between the selected side of each first type pad 3021 and the selected side of the adjacent second type pad 3022 is greater than 30 μm and less than 100 μm. The first type pad 3021 is spaced apart from two second type pads 3022 respectively in the first direction D1 and the second direction D2, and any pad adjacent to the second type pad 3022 is spaced apart from the second type pad 3022 along the first direction D1 or the second direction D2.

It should be noted that although FIGS. 2 to 4 take individual pad groups 102, 202, and 302 as examples, the wiring substrate 100 may comprise at least two of them at the same time. In an embodiment, the wiring substrate 100 comprises a plurality of pad groups, some of the plurality of pad groups are pad groups 102, the two pads 1021-P and 1021-N of each pad group 102 are configured to be respectively connected to two pins of the light-emitting element; the others of the plurality of pad groups are pad groups 302, and the twelve pads of each pad group 302 are configured to be respectively connected to twelve pins of the driver chip. In an alternative embodiment, the wiring substrate 100 comprises a plurality of pad groups, some of the plurality of pad groups are pad groups 102, the two pads 1021-P and 1021-N of each pad group 102 are configured to be respectively connected to two pins of the light-emitting element; and the others of the plurality of pad groups are pad groups 202, and the four pads of each pad group 202 are configured to be respectively connected to four pins of the driver chip.

In the example of FIG. 4, the arrangement of the pads is optimized so that the distance T between two opposite selected sides of two adjacent pads is greater than or equal to 30 μm and less than 100 μm. The setting of the value of the distance T provides a reasonable space for subsequent soldering with the pin of the electronic element. On the premise that there is no insulating layer covering between two adjacent pads, on the one hand, the distance T can ensure that the pin will not come into contact with other pads that should not have an electrical connection with the pin, so as to avoid a short circuit; on the other hand, the distance T can also maximize the area of the surface of the pad facing the pin of the electronic element on the basis of avoiding short circuit, which increases the soldering area between the pad and the pin, and reduces or even avoids soldering defects such as weak soldering due to insufficient contact area.

It should be noted that for any of the pad groups 102, 202, and 302, in addition to the distance T between adjacent pads needing to meet the above requirements, the shapes, sizes, and areas of multiple pads in the same pad group may be the same or different from each other. The area of each pad in the same pad group ranges from 8000 to 14400 μm², and the ratio of the areas of any two pads among multiple pads in the same pad group ranges from 0.556 to 1.800. In an embodiment, the shape, size, and area of multiple pads in the same pad group may be adapted to the structural features of the corresponding pins of the connected electronic element, for example, each pad and the pin of the electronic element connected to the pad are similar to each other.

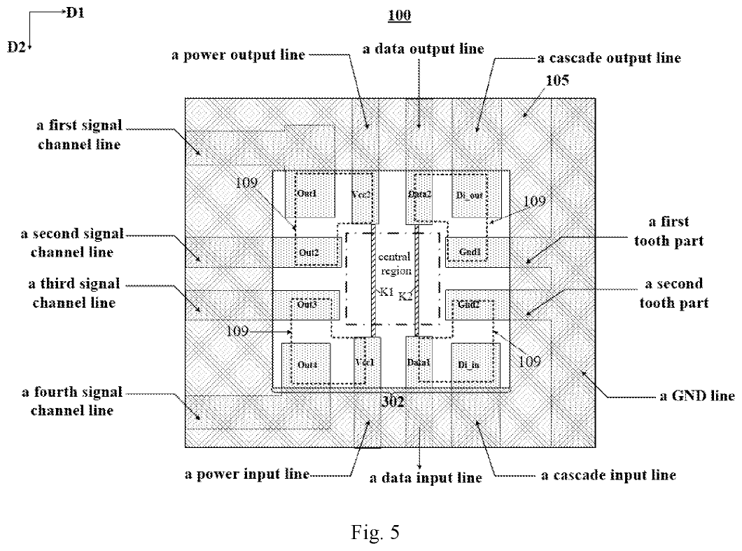

Referring to FIG. 5, the wiring substrate 100 may further comprise a soldering flux 109 on the surfaces of the plurality of pads of each pad group facing away from the base substrate. In FIG. 5, an example is given in which the pad group is the pad group 302. The soldering flux 109 is mainly distributed in four regions, and each region comprises one first type pad 3021 and two second type pads 3022. Within each region, the soldering flux 109 is disposed on the surfaces of the first type pad 3021 and the second type pads 3022 facing away from the base substrate and in the zone between the adjacent first type pad 3021 and the second type pad 3022. As illustrated in FIG. 5, the orthographic projection of the soldering flux 109 on the base substrate does not overlap with the orthographic projection of the central region of the pad group 302 on the base substrate, that is, the soldering flux 109 is not disposed in the central region of the pad group 302. Moreover, the plurality of pads are not provided in the central region of the pad group 302. Such arrangement of the soldering flux 109 depends on the shape of the opening of the mesh used in the manufacturing process. The structure of the mesh will be described in detail later, and will not be described in detail here.

The soldering flux 109 can help and promote the soldering between the pad and the pin during the reflow soldering process, while also plays the role of protection and prevention from oxidation. Since no pads are provided in the central region of the pad group 302, there is no need to form the soldering flux 109 in the central region. In the related art, a mesh is used to dispose the soldering flux, and the opening of the mesh corresponds to the region where the entire pad group 302 is located. In this way, the soldering flux 109 is not only formed on the surfaces of all pads in the pad group facing away from the base substrate, but also formed in the central region of the pad group where no pads are provided. When the pad group comprises a large number of pads, the soldering flux may remain in the central region of the pad group and cannot be effectively discharged, which can cause the soldering flux left in the central region to corrode the pad group and/or the pins connected to the pads. In contrast, in embodiments of the present disclosure, the soldering flux 109 is only disposed on the surfaces of the plurality of pads of the pad group 302 facing away from the base substrate and in the zone between the adjacent first type pad 3021 and the second type pad 3022, not disposed in the central region of the pad group 302. Therefore, the soldering flux 109 can be prevented from remaining in the central region of the pad group 302, thereby preventing the soldering flux 109 from corroding the pad group 302 and/or the pins connected to the corresponding pads of the pad group 302.

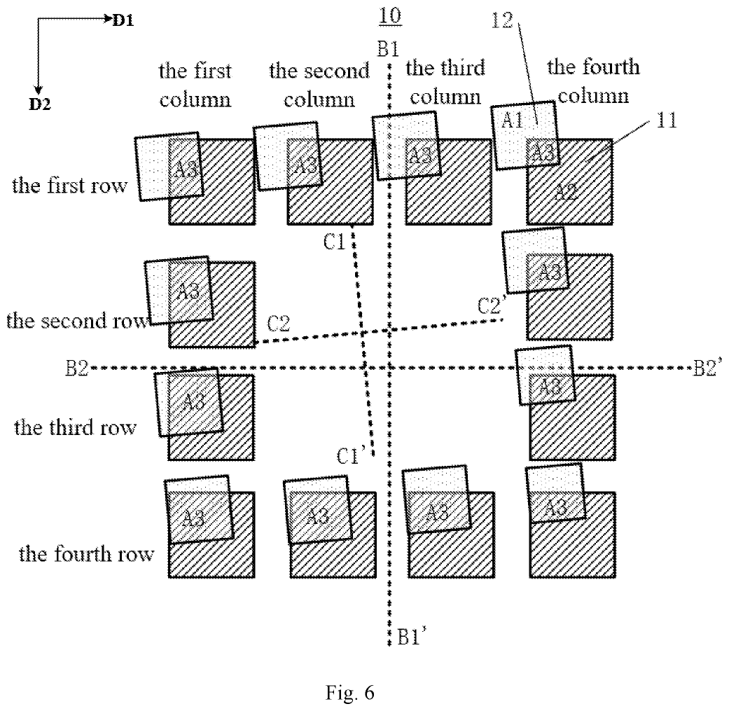

FIG. 6 illustrates the relative positional relationship between each pad 11 in a pad group of the light-emitting substrate 10 and the pin 12 of the corresponding electronic element after soldering in the related art. The size and shape of pads 11 are basically the same. Line B1B1′ and line B2B2′ in FIG. 6 are perpendicular to each other, and the cross dotted line formed by them represents the reference coordinate axis. The intersection of line B1B1′ and line B2B2′ may be understood as the geometric center of a pad group, the pads 11 in a pad group are arranged in an array based on the reference coordinate axis, wherein line B1B1′ is parallel to the second direction D2, and line B2B2′ is parallel to the first direction D1. A plurality of pins 12 of the electronic element are connected to the pads 11 of the above-mentioned pad group in a one to one correspondence. Line C1C1′ and line C2C2′ are perpendicular to each other. The intersection of line C1C1′ and line C2C2′ may be understood as the geometric center of the electronic element soldered to the pad group, and the plurality of pins 12 of the electronic element are arranged in an array based on the coordinate axis formed by the cross dotted line formed by the line C1C1′ and the line C2C2′. The angle between the line C1C1′ and the line B1B1′ (i.e. the second direction D2) is an acute angle, and the angle between the line C2C2′ and the line B2B2′ (i.e. the first direction D1) is an acute angle, that is, each pin 12 is deflected relative to the corresponding pad 11. The soldering process comprises steps such as alignment of pin and pad and soldering of pin and pad. In an ideal situation, after the pin 12 is aligned with the pad 11, the pin 12 will be accurately soldered to the predetermined position of the pad 11. That is, the intersection of line B1B1′ and line B2B2′ basically coincides with the intersection of line C1C1′ and line C2C2′, the angle between the line C1C1′ and the line B1B1′ (i.e., the second direction D2) is almost 0, and the angle between the line C2C2′ and the line B2B2′ (i.e., the first direction D1) is almost 0, that is, the pin 12 will not rotate and/or offset undesirably relative to the pad 11. However, due to factors such as alignment accuracy and process deviations, during the actual soldering process, the pin 12 soldered to the pad 11 always inevitably rotates and offsets to a certain extent relative to the pad 11, as illustrated in FIG. 6. Therefore, in the actual process, the pin 12 soldered to the pad 11 is allowed to have a certain degree of rotation and offset relative to the pad 11. However, if the rotation and offset angle of the pin 12 is too large, the contact area between the pin 12 and the pad 11 will be lower than the required lower limit, resulting in insufficient soldering overlap area between the pin 12 and the pad 11 and soldering defects such as weak soldering, thus affecting the soldering yield. Compared with a driver chip with four pins, a driver chip with twelve pins is larger in size. Under the same rotation angle, the relative offset of the edge pins of the driver chip with twelve pins will increase significantly, resulting in a more insufficient soldering overlap area, which in turn more easily lead to soldering defects such as weak soldering.

As illustrated in FIG. 6, in the related art, the four sides of each pad 11 are expanded relative to the four sides of the pin 12 to increase the contact area between the pin 12 and the pad 11, for example, the length of each side of the pad 11 is extended by 15 μm relative to the length of the corresponding side of the pin 12. Each side of the pad 11 is expanded, which causes the distance between two adjacent pads 11 to become smaller, especially for the pads 11 in the first row of FIG. 6, a part of the orthographic projection of the side of the pin 12 in the first row and second column close to the pad 11 in the first row and first column on the base substrate basically overlaps with a part of the orthographic projection of the side of the pad 11 in the first row and first column close to the pin 12 in the first row and second column on the base substrate, a part of the orthographic projection of the side of the pin 12 in the first row and third column close to the pad 11 in the first row and second column on the base substrate basically overlaps with a part of the orthographic projection of the side of the pad 11 in the first row and second column close to the pin 12 in the first row and third column on the base substrate. When the light-emitting substrate 10 is provided with both the first insulating layer 14 and the second insulating layer 15, the first insulating layer 14 may be disposed in a region between two adjacent pads 11 to insulate the pin 12 and the adjacent pad 11. Thus, even if the distance between two adjacent pads 11 becomes smaller due to the expansion of the pad 11, a short circuit between the pin 12 and the adjacent pad 11 will basically not occur.

Regarding the wiring substrate 100 provided by the embodiments of the present disclosure, as mentioned above, in order to reduce the thickness of the wiring substrate 100 and reduce the production cost, only one insulating layer 105 having both reflective and insulating functions is provided, and the first opening 1051 of the insulating layer 105 exposes portions of multiple signal lines to form multiple pads. Therefore, there is no insulating layer between adjacent pads. If this application continues to use the design scheme in which each side of the pad is equally expanded in the related art, the small distance between adjacent pads will cause the pin to contact with the adjacent pad so as to lead to a short circuit. In addition, since the first opening 1051 of the insulating layer 105 exposes each pad, if the area of the pad is significantly larger than the area of the pin due to the expansion, it means that the pad will have a larger non-soldering surface area and the non-soldering surface will be exposed by the first opening 1051, which may easily cause water and oxygen in the environment to intrude into the exposed non-soldering surface of the pad 11, thereby increasing the risk of corrosion.

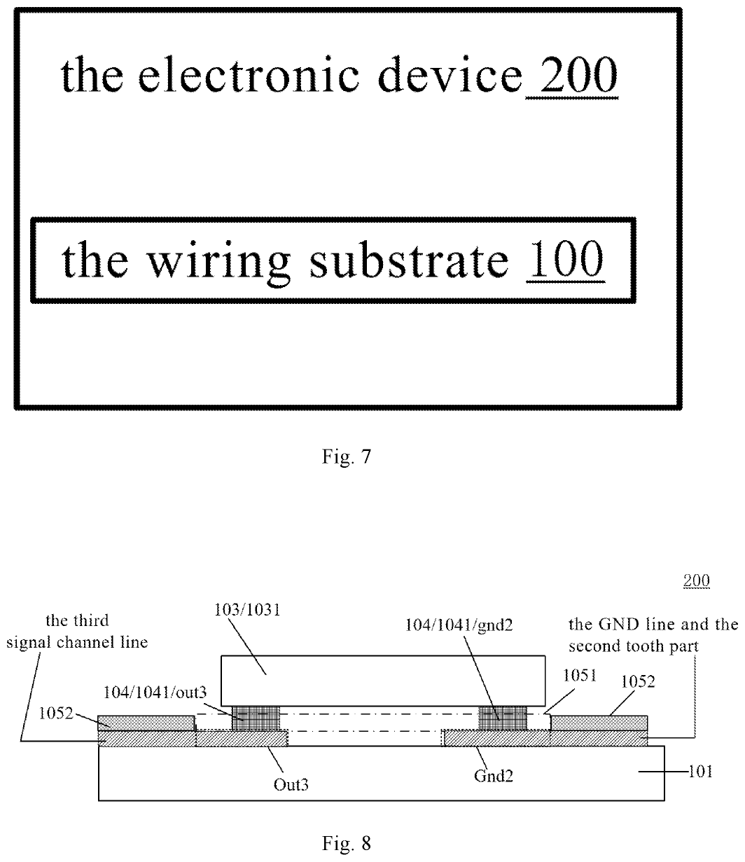

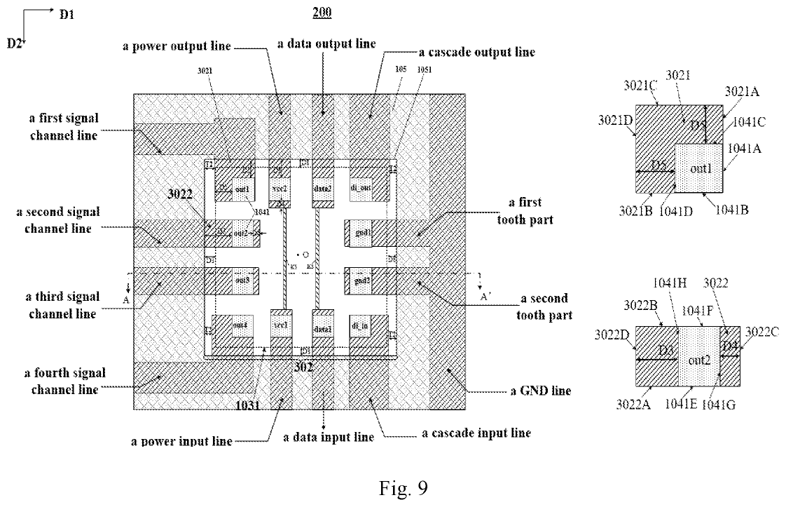

In view of this, embodiments of the present disclosure provide an electronic device, FIG. 7 illustrates a block diagram of the electronic device 200, and FIG. 8 illustrates a cross-sectional view of a partial structure of the electronic device 200. The structure of FIG. 8 can be obtained by cutting along the line AA′ of FIG. 9. For the sake of brevity, FIG. 9 omits some components such as the base substrate 101 and multiple signal lines. Referring to FIGS. 7-9, the electronic device 200 comprises the wiring substrate 100 described in any of the previous embodiments and a plurality of electronic elements 103. The plurality of electronic elements 103 are located on a side of the plurality of pad groups away from the base substrate, and any one of the plurality of electronic elements 103 corresponds to one of the plurality of pad groups. Each electronic element 103 comprises a pin group 104 comprising at least two pins 1041, any one of the at least two pins 1041 corresponds to one of the at least two pads, and the pin 1041 of each electronic element 103 is connected to a corresponding one of the pads. The pad group may be any of the pad groups 102, 202, and 302 described in the previous embodiments, and the electronic element 103 may comprise the light-emitting element and the driver chip. The light-emitting element may be a micro-light-emitting diode (Micro-LED) in the order and below the order of hundreds of microns or a sub-millimeter light-emitting diode (Mini-LED). The driver chip can be used to provide signals to the light-emitting elements to cause the light-emitting elements to emit light.

The electronic device 200 may be any suitable type of electronic device, for example, it may be any product or component with a display function, such as a television, a laptop, a tablet, a wearable display device, a mobile phone, a vehicle-mounted display, a navigation, an e-book, a digital photo frame, an advertising light box, etc. In an embodiment, the electronic device 200 may be used as a backlight of a liquid crystal display panel. In another embodiment, the electronic device 200 may be a liquid crystal display device which has more uniform backlight brightness and better display contrast.

FIG. 9 illustrates the relative positional relationship between the pin 1041 and the corresponding pad during the alignment process of the manufacturing process (before soldering). For the sake of simplicity, FIG. 9 omits some components such as multiple signal lines and the base substrate 101, but as mentioned above, the pad is obtained by exposing a portion of the signal line by the first opening 1051 of the insulating layer 105. In FIG. 9, as an example, the pad group is the pad group 302 described in the previous embodiment, and the electronic element 103 is a driver chip 1031 with twelve pins 1041. As illustrated in FIG. 9, the driver chip 1031 comprises four output pins out1, out2, out3, and out4, two power pins vcc1 and vcc2, two data pins data1 and data2, two ground pins gnd1 and gnd2, an address pin di_in and a relay pin di_out. Each output pin can be connected to at least one light-emitting element (not illustrated), so one driver chip 1031 can drive at least four light-emitting elements. Compared with the solution where one driver chip has only one output pin, the number of driver chips 1031 may be reduced by multiple times, which greatly reduces the usage of the driver chips 1031, thereby reducing the cost of the electronic device 200. The address pin di_in is configured to receive an address signal, to configure the address information of the driver chip 1031 according to the address signal, and to generate a relay signal. The relay pin di_out is connected to the address pin di_in of the next driver chip 1031 cascaded with the driver chip 1031, and configured to output the relay signal which is used as the address signal of the next driver chip 1031. The data pins data1 and data2 are configured to receive drive data, which comprises information such as the drive information and the address verification information. The power pins vcc1 and vcc2 are configured to receive the power signal to provide the voltage required for the operation of the driver chip 1031 to ensure the normal operation of the driver chip 1031. The ground pins gnd1 and gnd2 are configured to receive the ground signal.

It should be noted that although FIG. 9 illustrates the arrangement positions of the twelve pins 1041 of the driver chip 1031, this is only an example, and the arrangement positions of the twelve pins of the driver chip 1031 may be flexibly changed according to specific needs.

As illustrated in FIG. 9, the orthographic projection of each pin 1041 on the base substrate does not exceed the orthographic projection of the corresponding pad on the base substrate. As mentioned before, the pad group 302 comprises the first type pads 3021 and the second type pads 3022, the first type pads 3021 are the pads respectively soldered to the pins out1, out4, di_out, and di_in, and the second type pads 3022 are the pads respectively soldered to the pins out2, out3, gnd1, gnd2, vcc1, vcc2, data1, and data2.

As mentioned before, each first type pad 3021 comprises the first selected side 3021A, the second selected side 3021B, the first non-selected side 3021C and the second non-selected side 3021D. The pin 1041 soldered to the first type pad 3021 comprises four sides. The upper right of FIG. 9 is an enlarged view of the output pin out1 and the corresponding first type pad 3021 in the left figure. Taking the pin out1 as an example, this pin includes a first side 1041A, a second side 1041B, a third side 1041C and a fourth side 1041D. The other three pins out4, di_out, and di_in comprise the same four sides. When aligning, taking the pin out1 and the first type pad 3021 (i.e. the pad Out1) as an example, the first selected side 3021A and the second selected side 3021B of the first type pad 3021 are respectively aligned with the first side 1041A and the second side 1041B of the pin out1 in the direction perpendicular to the base substrate. The distance between the orthographic projection of the first non-selected side 3021C of the first type pad 3021 on the base substrate and the orthographic projection of the third side 1041C of the pin out1 on the base substrate is D5, and the distance between the orthographic projection of the second non-selected side 3021D of the first type pad 3021 on the base substrate and the orthographic projection of the fourth side 1041D of the pin out1 on the base substrate is D5. D5 is in the range of 20˜50 μm, for example, D5 may be 20 μm, 25 μm, 30 μm, 35 μm, 40 μm, 45 μm, 50 μm, etc. In other words, for the first type pad 3021, since there is an adjacent second type pad 3022 within 100 μm of the first selected side 3021A in the first direction D1, the first selected side 3021A does not expand outward relative to the first side 1041A of the pin 1041; since there is an adjacent second type pads 3022 within 100 μm of the second selected side 3021B in the second direction D2, the second selected side 3021B does not expand outward relative to the second side 1041B of the pin out1; since there is no adjacent pad within 100 μm of the first non-selected side 3021C in the second direction D2, the first non-selected side 3021C can expand outward by the distance D5 relative to the third side 1041C of the pin out1; since there is no adjacent pad within 100 μm of the second non-selected side 3021D in the first direction D1, the second non-selected side 3021D can expand outward by the distance D5 relative to the fourth side 1041D of the pin out1. The relative positional relationship between the other three pins out4, di_out, di_in and their corresponding pads is the same as the relative positional relationship between the pin out1 and the first type pad 3021, which will not be described again for the sake of simplicity.

The sides of the first type pad 3021 that are less than 100 μm apart from the adjacent pad (i.e., the selected sides 3021A and 3021B) are not expanded outward, in this way, the short circuit caused by the pin coming into contact with other pads that should not have electrical connection with the pin due to the small distance between two adjacent pads can be avoided. The sides of the first type pad that are greater than 100 μm apart from the adjacent pad (i.e., the non-selected sides 3021C and 3021D) expand outward by D5 relative to the side of the pin, in this way, the surface area of the first type pad 3021 facing the pin can be increased as much as possible while ensuring that short circuit is avoided, thereby increasing the soldering contact area between the first type pad 3021 and the pin, reducing or even avoiding soldering defects such as weak soldering caused by insufficient contact area between the pin and the first type pad 3021, and improving the soldering yield.

As previously mentioned, each second type pad 3022 comprises the third selected side 3022A, the fourth selected side 3022B, the first non-selected side 3022D, and the third non-selected side 3022C. The pin 1041 corresponding to the second type pad 3022 comprises four sides. The lower right of FIG. 9 is an enlarged view of the output pin out2 and the second type pad 3022 (i.e., the pad Out2) soldered to the output pin out2 in the left figure. Taking the pin out2 as an example, this pin comprises a fifth side 1041E, a sixth side 1041F, a seventh side 1041G and an eighth side 1041H. The other seven pins out3, gnd1, gnd2, vcc1, vcc2, data1, and data2 comprise the same four sides. When aligning, the third selected side 3022A and the fourth selected side 3022B of the second type pad 3022 are respectively aligned with the fifth side 1041E and the sixth side 1041F of the pin out2 in the direction perpendicular to the base substrate. The distance between the orthographic projection of the first non-selected side 3022D of the second type pad 3022 on the base substrate and the orthographic projection of the eighth side 1041H of the pin out2 on the base substrate is D3. D3 is in the range of 20˜50 μm, for example, D3 may be 20 μm, 25 μm, 30 μm, 35 μm, 40 μm, 45 μm, 50 μm, etc. The distance between the orthographic projection of the third non-selected side 3022C of the second type pad 3022 on the base substrate and the orthographic projection of the seventh side 1041G of the pin out2 on the base substrate is D4. D4 is in the range of 0˜30 μm, for example, D4 may be 5 μm, 10 μm, 15 μm, 20 μm, 25 μm, 30 μm, etc. The third non-selected side 3022C of the second type pad 3022 is closer to the center O of the pad group 302 than the first non-selected side 3022D. In other words, for the second type pad 3022, since there is another adjacent second type pad 3022 within 100 μm of the third selected side 3022A along the second direction D2, the third selected side 3022A does not expand outward relative to the fifth side 1041E of the pin out2; since there is another adjacent first type pad 3021 within 100 μm of the fourth selected side 3022B along the second direction D2, the fourth selected side 3022B does not expand outward relative to the sixth side 1041F of the pin out2; since there is no adjacent pad within 100 μm of the first non-selected side 3022D along the first direction D1, the first non-selected side 3022D may expand outward by the distance D3 relative to the eighth side 1041H of the pin out2; since there is no adjacent pad within 100 μm of the third non-selected side 3022C along the first direction D1, the third non-selected side 3022C may expand outward by the distance D4 relative to the seventh side 1041G of the pin out2. The relative positional relationship between the other seven pins out3, gnd1, gnd2, vcc1, vcc2, data1, data2 and their corresponding pads is the same as the relative positional relationship between the pin out2 and the second type pad 3022. For the sake of brevity, no further details will be given.

The sides of the second type pad 3022 that are less than 100 μm apart from the adjacent pad (i.e., the selected sides 3022A and 3022B) are not expanded outward, in this way, the short circuit caused by the pin coming into contact with other pads that should not have electrical connection with the pin due to the small distance between two adjacent pads can be avoided. The sides of the second type pad 3022 that are greater than 100 μm apart from the adjacent pad (i.e., the non-selected sides 3022C and 3022D) expand outward respectively by D3 and D4 relative to the sides of the pin, in this way, the surface area of the second type pad 3022 facing the pin can be increased as much as possible while ensuring that short circuit is avoided, thereby increasing the soldering contact area between the second type pad 3022 and the pin, reducing or even avoiding soldering defects such as weak soldering caused by insufficient contact area between the pin and the second type pad 3022, and improving the soldering yield. Further, since the third non-selected side 3022C is closer to the center O of the pad group 302 than the first non-selected side 3022D, the expansion distance D4 of the third non-selected side 3022C relative to the seventh side 1041G of the pin may be smaller than the expansion distance D3 of the first non-selected side 3022D relative to the eighth side 1041H of the pin. Therefore, the distance between two opposite third non-selected sides 3022C of two adjacent second type pads 3022 may be prevented from being too small.

As illustrated in FIG. 9, the area of the surface of each pin 1041 facing the corresponding pad is C1, and the range of C1 is 6400˜12100 μm². The area of the surface of the corresponding pad facing the pin 1041 is C2, and the range of C2 is 8000˜14400 μm². The ratio of C1 to C2 is 0.4˜1.0. For example, the ratio of C1 to C2 may be 0.4, 0.6, 0.8, 1.0, etc.

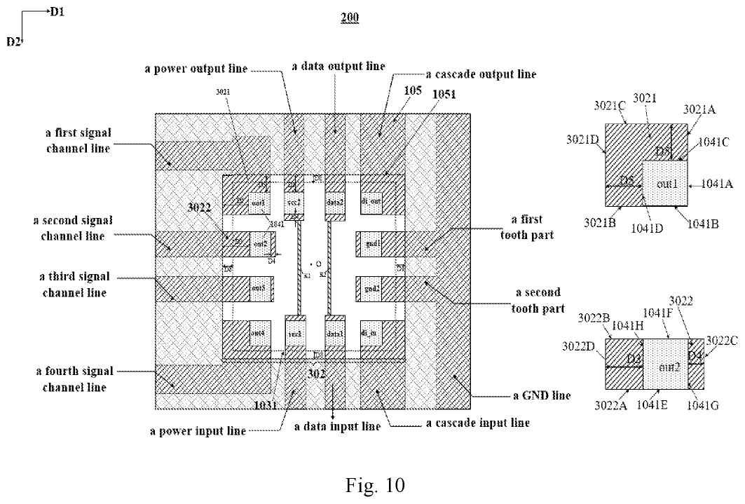

As illustrated in FIG. 9, the orthographic projection of the first non-selected side 3021C of the first type pad 3021 on the base substrate coincides with the partial contour of the orthographic projection of the first opening 1051 of the insulating layer 105 on the base substrate. The minimum distance between the orthographic projection of the second non-selected side 3021D of the first type pad 3021 on the base substrate and the contour of the orthographic projection of the first opening 1051 of the insulating layer 105 on the base substrate is T2. The range of T2 is 30˜50 μm. For example, T2 may be 30 μm, 40 μm, 50 μm, etc. FIG. 10 is a variant of FIG. 9. Except for the first type pad 3021, other structures of FIG. 10 are the same as the structures of FIG. 9. In FIG. 10, the orthographic projections of the first non-selected side 3021C and the second non-selected side 3021D of the first type pad 3021 on the base substrate respectively coincide with the partial contour of the orthographic projection of the first opening 1051 of the insulating layer 105 on the base substrate.

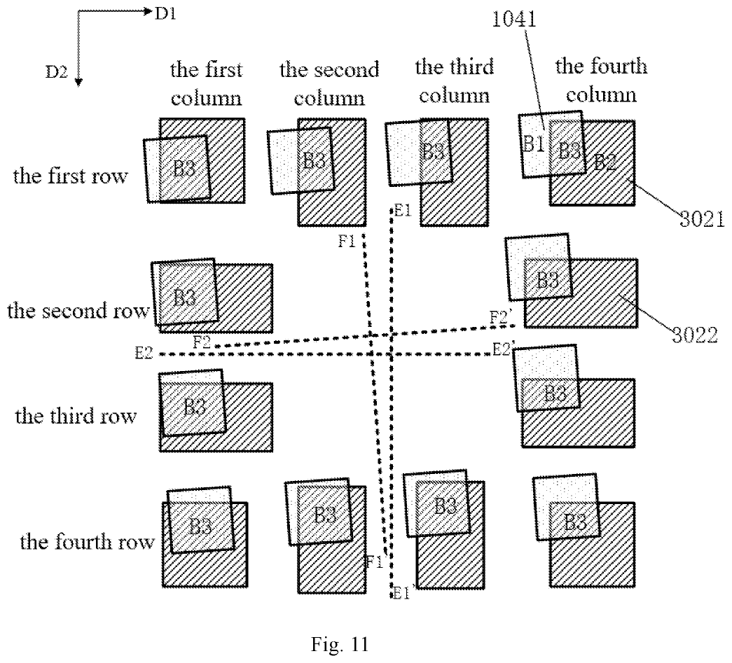

FIG. 11 illustrates the relative positional relationship between the pads of a pad group 302 of the electronic device 200 (which comprises four first type pads 3021 and eight second type pads 3022 as shown in FIG. 4) and the pins 1041 of a corresponding electronic element after soldering, as provided by an embodiment of the present disclosure. Line E1E1′ and line E2E2′ in FIG. 11 are perpendicular to each other, and the cross dotted line formed by them represents the reference coordinate axis. The intersection of line E1E1′ and line E2E2′ can be understood as the geometric center of the pad group 302. The pads in the pad group 302 are arranged in an array based on the reference coordinate axis, wherein the line E1E1′ is parallel to the second direction D2, and the line E2E2′ is parallel to the first direction D1. A plurality of pins 1041 of the electronic element are connected to the pads of the above-mentioned pad group 302 in a one-to-one correspondence. The line F1F1′ is perpendicular to the line F2F2′. The intersection of the line F1F1′ and the line F2F2′ can be understood as the geometric center of the electronic element soldered to the above-mentioned pad group 302, and the plurality of pins 1041 of the electronic element are arranged in an array based on the coordinate axis formed by the cross dotted line formed by the line F1F1′ and the line F2F2′. The angle between the line F1F1′ and the line E1E1′ is an acute angle, and the angle between the line F2F2′ and the line E2E2′ is an acute angle. It can be seen that the pin 1041 has a certain rotation and offset (for example, the rotation angle and offset angle are the same as those in the related art illustrated in FIG. 6) relative to the first type pad 3021 or the second type pad 3022 of the pad group 302. The rotation angle of the pin 1041 relative to the first type pad 3021 or the second type pad 3022 connected thereto is not greater than 3 degrees, and the offset size of the pin 1041 relative to the first type pad 3021 or the second type pad 3022 connected thereto is not greater than 36 μm. Under such rotation angle and offset size, the contact area between the pin 1041 and the pad in the pad group can meet the requirements, so that the two can be reliably connected. As illustrated in FIG. 11, the orthographic projection of each pin 1041 on the base substrate is a first orthographic projection B1, the orthographic projection of the pad 3021 or 3022 soldered to the pin 1041 on the base substrate is a second orthographic projection B2. The first orthographic projection B1 and the second orthographic projection B2 at least partially overlap. The region where the first orthographic projection B1 and the second orthographic projection B2 overlap constitutes an overlapping region B3, and the ratio of the area of the overlapping region B3 to the area of the second orthographic projection B2 is greater than or equal to 39%. In some embodiments, the ratio of the area of the overlapping region B3 to the area of the second orthographic projection B2 ranges from 39% to 100%, that is, the minimum value of the ratio of the area of the overlapping region B3 to the area of the second orthographic projection B2 is 39%, and the maximum value of the ratio of the area of the overlapping region B3 to the area of the second orthographic projection B2 is 100%. For a pad group, the ratio of the smallest area to the largest area among the areas of the overlapping regions B3 is approximately 0.5. In contrast, in the related art, referring to FIG. 6, the orthographic projection of each pin 12 on the substrate is a first orthographic projection A1, the orthographic projection of the pad 11 soldered to the pin 12 on the substrate is a second orthographic projection A2, and the first orthographic projection A1 and the second orthographic projection A2 at least partially overlap to form an overlapping region A3. The ratio of the area of the overlapping region A3 to the area of the second orthographic projection A2 is greater than or equal to 31%. For a pad group, the minimum value of the ratio of the smallest area to the largest area among the areas of the overlapping regions A3 is, for example, 0.25. Compared with the related art, in the embodiments of the present disclosure, by designing the selected sides and non-selected sides of the first type pad 3021 and the second type pad 3022 respectively as mentioned above, not only the risk of short circuit can be avoid, but also the soldering contact area between the pin 1041 and the first type pad 3021 or the second type pad 3022 can be significantly increased, the soldering defects such as weak soldering due to insufficient contact area between the pin 1041 and the first type pad 3021 or the second type pad 3022 can be reduced or even avoided, thus helping to improve the soldering yield. In addition, referring to FIG. 6, in the related art, among the twelve pads 11, only four pads satisfy that the ratio of the area of the overlapping region A3 to the area of the second orthographic projection A2 is greater than 40%, while for the other eight pads, the ratio of the area of the overlapping region A3 to the area of the second orthographic projection A2 is significantly less than 40%. In particular, for the pad 11 and pin 12 located in the first row and the fourth column, the ratio of the area of the overlapping region A3 to the area of the second orthographic projection A2 is the smallest, for example, less than 20%. In the example of FIG. 6, the ratio of the area of the overlapping region A3 to the area of the second orthographic projection A2 ranges from approximately 20% to 100%. In contrast, in the embodiment of the present disclosure, referring to FIG. 11, among the twelve pads, at least eleven pads satisfy that the ratio of the area of the overlapping region B3 to the area of the second orthographic projection B2 is greater than 40%, and there is only one pad whose ratio of the area of the overlapping region B3 to the area of the second orthographic projection B2 is slightly less than 40%. Therefore, compared with the related art, a larger number of pads satisfy that the ratio of the area of the overlapping region B3 to the area of the second orthographic projection B2 is greater than 40%, which further ensures the soldering contact area between the pin 1041 and the first type pad 3021 or the second type pad 3022, avoids insufficient soldering contact area between the pin 1041 and the first type pad 3021 or the second type pad 3022, thereby helping to further improve the soldering yield.

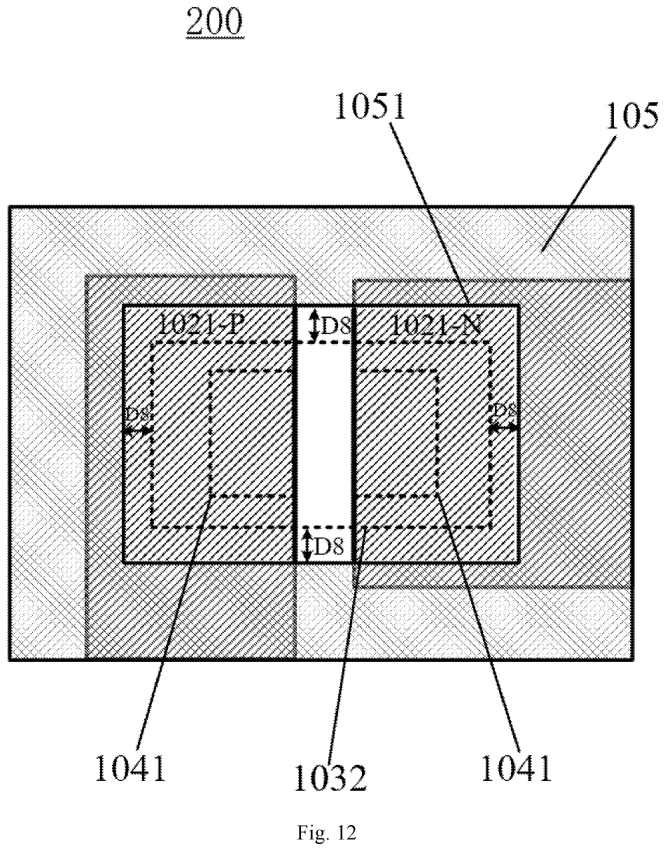

Referring to FIG. 8, the insulating layer 105 is located between the plurality of pad groups and the plurality of electronic elements 103, and any one of the plurality of electronic elements 103 corresponds to one of the plurality of first openings 1051 of the insulating layer 105. In an embodiment, as illustrated in FIG. 9, when the pad group is the pad group 302 and the electronic element 103 is the driver chip 1031, the insulating layer 105 is located between the plurality of pad groups 302 and the plurality of driver chips 1031, and any one of the plurality of driver chips 1031 corresponds to one of the plurality of first openings 1051 of the insulating layer 105. The third orthographic projection of each driver chip 1031 on the base substrate falls within the fourth orthographic projection of the corresponding first opening 1051 on the base substrate, and the distance between the contour of the third orthographic projection and the contour of the fourth orthographic projection is D8. D8 may be 20˜40 μm, such as 20 μm, 25 μm, 30 μm, 35 μm, 40 μm, etc. The first opening 1051 of the insulating layer 105 is expanded by D8 relative to the contour of the driver chip 1031, which can provide a redundancy to provide a tolerance range during the process, at the same time, the driver chip 1031 can also be limited in situ from the first direction D1 and the second direction D2 during the die-bonding process. In another embodiment, as illustrated in FIG. 12, when the pad group is the pad group 102 with two pads and the electronic element 103 is the light-emitting element 1032, the insulating layer 105 is located between the plurality of pad groups 102 and the plurality of light-emitting elements 1032, and any one of the plurality of light-emitting elements 1032 corresponds to one of the plurality of first openings 1051 of the insulating layer 105. The third orthographic projection of each light-emitting element 1032 on the base substrate falls within the fourth orthographic projection of the corresponding first opening 1051 on the base substrate, and the distance between the contour of the third orthographic projection and the contour of the fourth orthographic projection is D8. D8 may be 20˜40 μm, such as 20 μm, 25 μm, 30 μm, 35 μm, 40 μm, etc. The first opening 1051 of the insulating layer 105 is expanded D8 relative to the contour of the light-emitting element 1032, which can provide a redundancy to limit the light-emitting element 1032 in situ to some extent in the first direction D1 and the second direction D2.

In some embodiments, in order to meet the reflection requirements, the thickness of the insulating layer 105 in the direction perpendicular to the base substrate 101 is usually 50˜60 μm. At the same time, since the first opening 1051 of the insulating layer 105 expands by 20˜40 μm relative to the contour of the electronic element 103, the insulating layer 105 can limit the electronic element 103 in situ to some extent in the first direction D1 and the second direction D2, preventing the pin 1041 of the electronic element 103 from rotating and offsetting significantly relative to the pad during the die-bonding process. Therefore, the contact area between the pin 1041 and the pad after reflow soldering can be increased, and soldering defects such as weak soldering can be reduced or even avoided. The first opening 1051 of the insulating layer 105 expands by 20˜40 μm relative to the contour of the electronic element 103, which is an appropriate range, because, if the range of the expansion is too small, the offset amount of the pin 1041 during the die-bonding process will be limited, which may easily cause the local position of the electronic element 103 to come into contact with the surface of the insulating layer 105 facing the electronic element 103, causing the electronic element to roll over and making soldering impossible; if the range of the expansion is too large, the insulating layer 105 basically loses its limiting function, causing the pin 1041 of the electronic element 103 to rotate and/or offset too much relative to the pad, as a result, the contact area between the pin 1041 and the pad is easily reduced, the weak soldering occurs, and the risk of short circuit between the pin 1041 and the adjacent pad may be resulted.

The light-emitting element 1032 may be a micro light-emitting diode (Micro-LED) in the order and below the order of hundreds of microns or a sub-millimeter light-emitting diode (Mini-LED). The driver chip 1031 may be used to provide signals to the light-emitting element 1032 to enable the light-emitting element 1032 to emit light.

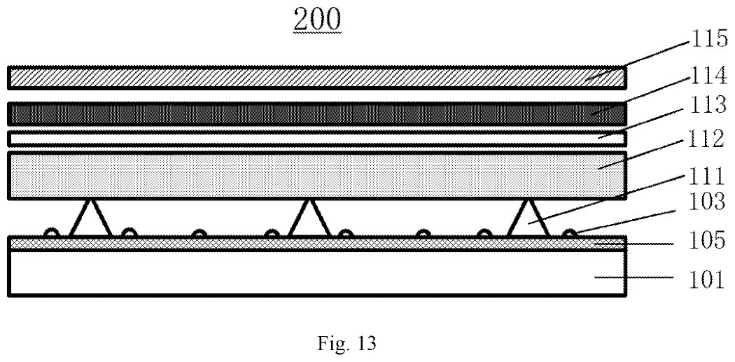

FIG. 13 illustrates a schematic cross-sectional view of the electronic device 200. As illustrated in FIG. 13, in addition to the base substrate 101, the insulating layer 105, and the electronic element 103, the electronic device 200 may also comprise structures such as a support pillar 111, a diffusion plate 112, a wavelength conversion layer 113, a diffusion sheet 114, and a composite film 115. The support pillar 111 is fixed on the insulating layer 105, which can provide a spacing between the diffusion plate 112 and the insulating layer 105, thereby obtaining a light mixing distance and reducing or eliminating the light shadow generated by the light-emitting element. The diffusion plate 112 and the diffusion sheet 114 can be used to further eliminate a potential light shadow and to improve the uniformity of the picture. The wavelength conversion layer 113 may, for example, convert blue light emitted by the light-emitting element into white light. In some embodiments, the wavelength converting layer 113 is a quantum dot film. The composite film 115 can be used to increase the brightness of the emitted light. The soldered electronic element (such as the light-emitting element, the driver chip, etc.) is protected by encapsulant.

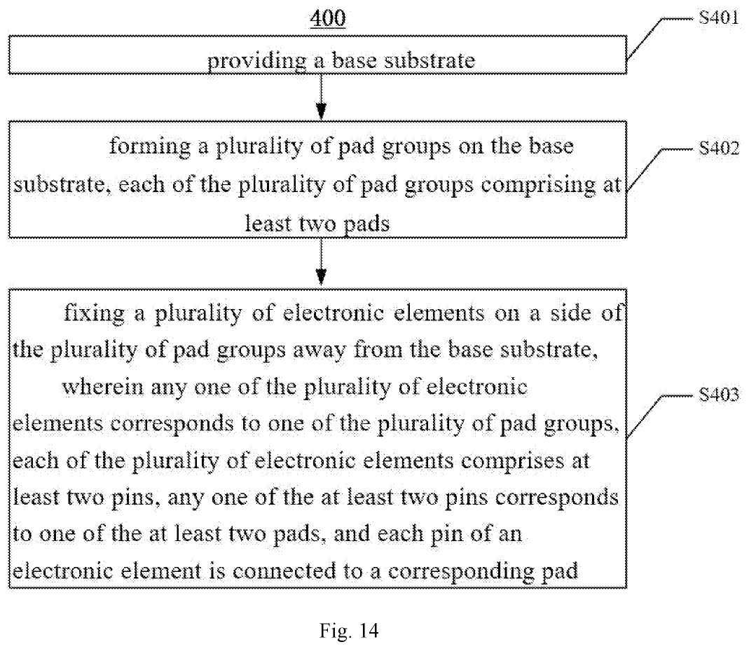

FIG. 14 illustrates a flow chart of a method 400 for manufacturing an electronic device. The method 400 is applicable to the electronic device described in any of the previous embodiments. The method 400 comprises the following steps:
S401: providing a base substrate.
S402: forming a plurality of pad groups on the base substrate, each of the plurality of pad groups comprising at least two pads.
S403: fixing a plurality of electronic elements on a side of the plurality of pad groups away from the base substrate, wherein any one of the plurality of electronic elements corresponds to one of the plurality of pad groups, each of the plurality of electronic elements comprises at least two pins, any one of the at least two pins corresponds to one of the at least two pads, and each pin of the electronic element is connected to a corresponding pad.

Some process details involved in the steps S401-S403 will be described below in detail.

S401: providing a base substrate.

The base substrate may be a flexible or rigid material. Specifically, it may be PEN resin, silicone resin, polyimide, glass, quartz, plastic, etc. The embodiments of the present disclosure do not limit the material of the base substrate.

S402: forming a plurality of pad groups on the base substrate, each of the plurality of pad groups comprising at least two pads.

Specifically, a conductive layer is formed on the base substrate, and the conductive layer is patterned to form a plurality of signal lines. An insulating layer 105 comprising a plurality of first openings 1051 is formed on a side of the plurality of signal lines away from the base substrate, and a portion of each signal line is exposed by the first opening 1051 to form a pad. The plurality of signal lines may comprise a power supply voltage signal line configured to provide a voltage to the light-emitting element 1032, a ground signal line configured to provide a ground voltage to the ground pin gnd of the driver chip, a transmission signal line configured to provide a data signal to the data pin data of the driver chip, a power supply voltage signal line configured to provide a voltage to the power pin vcc of the driver chip, etc. The pad group may be the pad group 102, 202, or 302 described in the previous embodiments.

Between steps S402 and S403, a step of applying soldering flux to the pin 1041 or the pad is also comprised. The soldering flux can help and promote the soldering between the pad and the pin in the subsequent reflow soldering process, while also plays the role of protection and prevention from oxidation. There are two methods of applying soldering flux. One method is: several driver chips are adhered and arranged on the UV film, the pins 1041 of the driver chips are on the side away from the UV film, the pins 1041 of all driver chips on the UV film are dipped into a tank provided with the soldering flux, so that the surfaces of all pins 1041 facing away from the UV film are covered with the soldering flux. This method of applying soldering flux is usually referred to as the “soldering flux dipping process”. Correspondingly, solder may be applied on the surface of the pad facing the pin 1041. When the driver chip is the driver chip with twelve pins as mentioned above, using this soldering flux dipping process, not only the surfaces of all pins 1041 facing away from the UV film are dipped with the soldering flux, but also the central region of the surface of the driver chip facing away from the UV film is dipped with the soldering flux. The central region of the driver chip does not provide any pins 1041, so in fact, the central region does not require the soldering flux. This soldering flux dipping process will cause the soldering flux to left in the central region of the driver chip and cannot be effectively discharged, causing the soldering flux to corrode the pins of the driver chip and the pads connected to the pins.

Another method of applying soldering flux is: the soldering flux is printed onto the surface of each pad of the pad group facing the pin 1041 by using a mesh with openings, such as a steel mesh, and for example, a dipping method may be used so that the surface of the pin 1041 facing the pad is dipped with solder. This method of applying soldering flux is usually referred to as the “soldering flux printing process”.

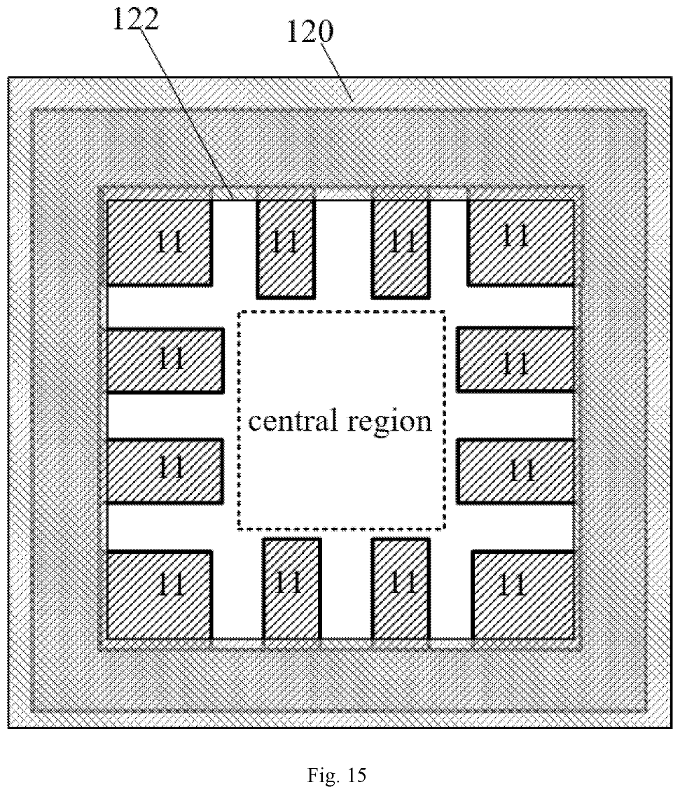

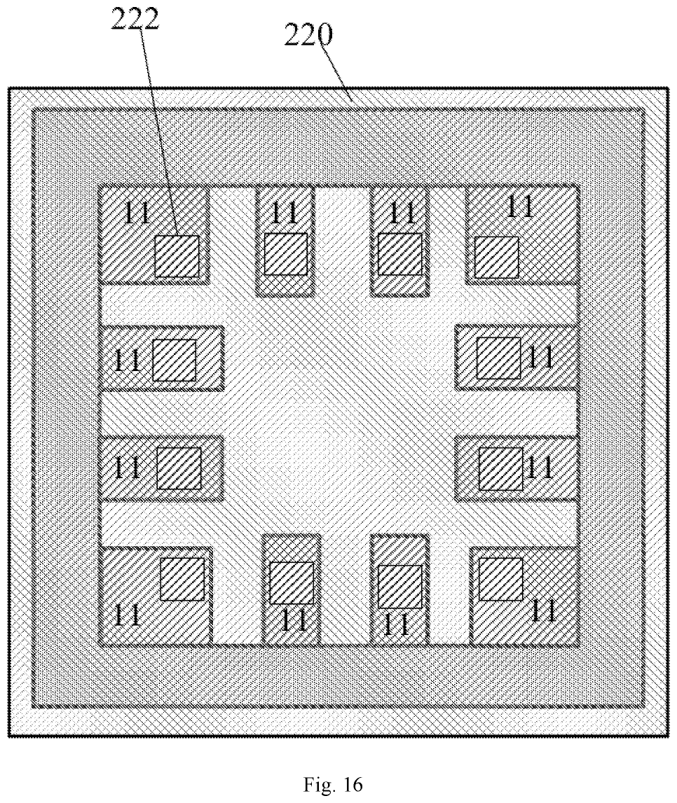

There are two approaches in the related art to form the soldering flux on the plurality of pads of the pad group by using the soldering flux printing process. One approach is, as illustrated in FIG. 15, the mesh 120 comprises an opening 122 at a position corresponding to each pad group, the opening 122 exposes all twelve pads 11 of the pad group as well as the central region of the pad group. The soldering flux is printed through the opening 122 onto the twelve pads 11 of each pad group and the central region of the pad group. However, this method is similar to the soldering flux dipping process, which causes the soldering flux to remain in the central region of the pad group where the pads 11 are not provided. Another approach is, as illustrated in FIG. 16, the mesh 220 is provided with an opening 222 at a position corresponding to each pad 11 of the pad group. The opening 222 exposes a portion of the surface of the pad 11 facing the pin 1041, and the soldering flux is printed onto the portion of the surface of each pad 11 facing the pin 1041 through the opening 222. Although this method can avoid printing the soldering flux at the central region of the pad group, since the mesh 220 comprises twelve openings 222 at positions corresponding to each pad group, a large number of pad groups are provided on the light-emitting substrate, which results in a large number of openings 222 on the entire mesh 220. When the mesh 220 needs to be separated from the base substrate after printing the soldering flux, due to the large number of openings 222, the adhesion force between the soldering flux and the mesh 220 and/or the base substrate will be significantly increased and the distance between two adjacent openings 222 corresponding to the same pad group is small, which results in insufficient strength and reduced tension of the mesh 220, makes it difficult to ensure the accuracy of removing the mesh 220 from the base substrate, and accelerates the wear of the mesh 220 and shorten the life of the mesh 220 because of the reduced strength and tension.

In view of this, embodiments of the present disclosure provide an improved mesh to optimize the printing process of the soldering flux.

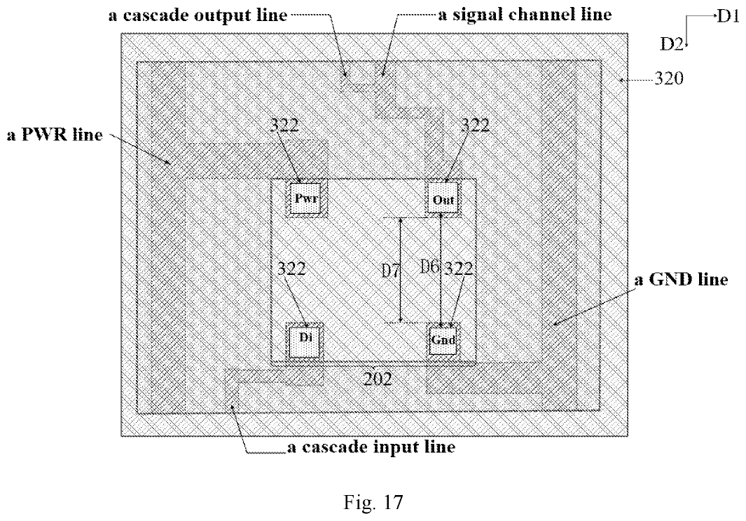

As illustrated in FIG. 17, when the pad group is the pad group 202 comprising four pads, the mesh 320 comprises four second openings 322 at positions corresponding to each pad group 202, and the orthographic projection of each opening 322 on the base substrate falls within the orthographic projection of a corresponding pad on the base substrate. The soldering flux can be printed through the second opening 322 to the surface of each pad facing the pin 1041 without printing the soldering flux into the central region of the pad group 202. This prevents the soldering flux from remaining in the central region of the pad group 202, and further prevents the soldering flux from corroding the pads of the pad group 202 and the corresponding pins of the electronic element connected to the pads. The distance D7 between two opposite sides of two adjacent pads is relatively large, which is about 140 μm. The distance D6 between two opposite profiles of two adjacent second openings 322 can be increased to 160 μm. The larger distance D6 can ensure that the mesh 320 has higher strength and tension.

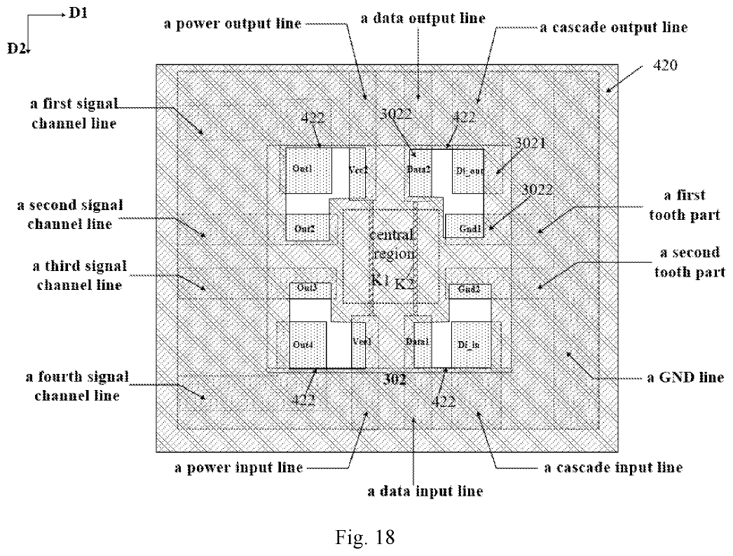

As illustrated in FIG. 18, when the pad group is the pad group 302 comprising twelve pads, each pad group 302 comprises a central region and four corner regions surrounding the central region. One first type pad 3021 and two second type pads 3022 are arranged in each corner region. The mesh 420 comprise a plurality of second openings 422, and any one of the plurality of second openings 422 corresponds to one of the plurality of corner regions of the plurality of pad groups 302. The orthographic projection of each second opening 422 on the base substrate partially overlaps with the orthographic projections of one first type pad 3021 and two second type pads 3022 within a corresponding corner region on the base substrate. That is, the mesh 420 comprises four second openings 422 at positions corresponding to each pad group 302. In some embodiments, the second opening 422 is shaped like an “L” shape, and each second opening 422 should expose at least one first type pad 3021 and at least two second type pads 3022 in the pad group 302. When the mesh 420 is used to print the soldering flux, the soldering flux is printed on the surfaces of the first type pad 3021 and the second type pad 3022 away from the base substrate through the second opening 422 of the mesh 420. After printing, the mesh 420 is removed.

Since the mesh 420 does not have an opening corresponding to the central region of the pad group 302, the soldering flux will not be printed to the central region of the pad group 302, thus preventing the soldering flux from remaining in the central region of the pad group 302 and preventing the soldering flux from corroding the pads of the pad group 302 and the corresponding pins of the electronic element connected to the pads. In the related art, at the position corresponding to each pad group, the number of openings 222 of the mesh 220 is twelve. In the embodiment of the present disclosure, at the position corresponding to each pad group 302, the number of the second openings 422 of the mesh 420 is reduced from twelve to four. Therefore, the strength and tension of the mesh 420 are significantly improved compared to the strength and tension of the mesh 220. Furthermore, reducing the number of the second openings 422 can effectively ensure the accuracy of separation of the mesh 420 from the base substrate.

S403: fixing a plurality of electronic elements on a side of the plurality of pad groups away from the base substrate.

Specifically, this step may comprise: aligning each pin 1041 of the electronic element with a corresponding pad, so that a first orthographic projection of each pin 1041 of the electronic element on the base substrate does not exceed a second orthographic projection of the corresponding pad on the base substrate; soldering each pin 1041 of the electronic element to the corresponding pad by a solder. Since the surface of the pin 1041 facing the pad has been dipped with solder comprising tin in the previous step, and the surface of the pad facing the pin 1041 has been printed with the soldering flux, the tin in the solder and the surface material of the pad can generate an intermetallic compound during the reflow process of the pin and the pad, and in combination with the promotion effect of the soldering flux, therefore, the pin 1041 can achieve a reliable electrical connection with the pad.

Referring to FIG. 9, when the pad group is the pad group 302, the step of aligning each pin 1041 of the electronic element with a corresponding pad may comprise the following sub-steps:
the first selected side 3021A and the second selected side 3021B of each first type pad 3021 are respectively aligned with the first side 1041A and the second side 1041B of a corresponding pin 1041 in the direction perpendicular to the base substrate, the orthographic projection of the first non-selected side 3021C of each first type pad 3021 on the base substrate is spaced apart from the orthographic projection of the third side 1041C of the corresponding pin 1041 on the base substrate by D5, and the orthographic projection of the second non-selected side 3021D of each first type pad 3021 on the base substrate is spaced apart from the orthographic projection of the fourth side 1041D of the corresponding pin 1041 on the base substrate by D5. D5 is in the range of 20˜50 μm, for example, D5 may be 20 μm, 25 μm, 30 μm, 35 μm, 40 μm, 45 μm, 50 μm, etc. In addition, the third selected side 3022A and the fourth selected side 3022B of each second type pad 3022 are respectively aligned with the fifth side 1041E and the sixth side 1041F of the corresponding pin 1041 in the direction perpendicular to the base substrate, the orthographic projection of the first non-selected side 3022D of each second type pad 3022 on the base substrate is spaced apart from the orthographic projection of the eighth side 1041H of the corresponding pin 1041 on the base substrate by D3, D3 is in the range of 20˜50 μm, for example, D3 may be 20 μm, 25 μm, 30 μm, 35 μm, 40 μm, 45 μm, 50 μm, etc, and the orthographic projection of the third non-selected side 3022C of each second type pad 3022 on the base substrate is spaced apart from the orthographic projection of the seventh side 1041G of the corresponding pin 1041 on the base substrate by D4, D4 is in the range of 0˜30 μm, for example, D4 may be 5 μm, 10 μm, 15 μm, 20 μm, 25 μm, 30 μm, etc.

The selected sides of the first type pad 3021 and the second type pad 3022 do not expand outward relative to the sides of the pin 1041, in this way, the short circuit caused by the pin 1041 coming into contact with the adjacent pad due to the small distance between adjacent pads can be avoided. The non-selected sides of the first type pad 3021 and the second type pad 3022 respectively expand outward to a certain extent relative to the sides of the pin 1041, in this way, the surface areas of the first type pad 3021 and the second type pad 3022 facing the pin 1041 can be increased as much as possible while ensuring that short circuit is avoided, thereby increasing the soldering contact area between the pin 1041 and the first type pad 3021 and second type pad 3022, reducing or even avoiding soldering defects such as weak soldering caused by insufficient contact area between the pin 1041 and the first type pad 3021 and second type pad 3022, and improving the soldering yield.

It will be understood that although the terms first, second, third, etc. may be used herein to describe various elements, components, regions, layers and/or portions, these elements, components, regions, layers and/or portions should not be limited by these terms. These terms are only used to distinguish an element, component, region, layer or portion from another element, component, region, layer or portion. Thus, a first element, component, region, layer or portion discussed above could be termed a second element, component, region, layer or portion without departing from the teachings of the present disclosure.

Spatially relative terms such as “row”, “column”, “below”, “above”, “left”, “right”, etc. may be used herein for ease of description to describe factors such as the relationship of an element or feature to another element(s) or feature(s) illustrated in the figures. It will be understood that these spatially relative terms are intended to encompass different orientations of the device in use or operation in addition to the orientation depicted in the figures. For example, if the device in the figures is turned over, elements described as “below” other elements or features would then be oriented “above” other elements or features. Thus, the exemplary term “below” can encompass both an orientation of above and below. The device may be otherwise oriented (rotated 90 degrees or at other orientations) and the spatially relative descriptors used herein are interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to limit the present disclosure. As used herein, the singular forms “a,” “an,” and “the” are intended to comprise the plural forms as well, unless the context clearly dictates otherwise. It will be further understood that the terms “comprise” and/or “include” when used in this specification designate the presence of stated features, integers, steps, operations, elements and/or parts, but do not exclude the presence or addition of one or more other features, integers, steps, operations, elements, components and/or groups thereof. As used herein, the term “and/or” comprises any and all combinations of one or more of the associated listed items. In the description of this specification, description with reference to the terms “an embodiment,” “another embodiment,” etc. means that a particular feature, structure, material, or characteristic described in connection with the embodiment is included in at least one embodiment of the present disclosure. In this specification, schematic representations of the above terms are not necessarily directed to the same embodiment or example. Furthermore, the particular features, structures, materials or characteristics described may be combined in any suitable manner in any one or more embodiments or examples. Furthermore, those skilled in the art may combine the different embodiments or examples as well as the features of the different embodiments or examples described in this specification without conflicting each other.

It will be understood that when an element or layer is referred to as being “on”, “connected to”, “coupled to”, or “adjacent to” another element or layer, it may be directly on, directly connected to, directly coupled to, or directly adjacent to another element or layer, or intervening elements or layers may be present. In contrast, when an element is referred to as being “directly on”, “directly connected to”, “directly coupled to”, “directly adjacent to” another element or layer, with no intervening elements or layers present. However, in no case should “on” or “directly on” be interpreted as requiring a layer to completely cover the layer below.

Embodiments of the disclosure are described herein with reference to schematic illustrations (and intermediate structures) of idealized embodiments of the disclosure. As such, variations to the shapes of the illustrations are to be expected, e.g., as a result of manufacturing techniques and/or tolerances. Accordingly, embodiments of the present disclosure should not be construed as limited to the particular shapes of the regions illustrated herein, but are to comprise deviations in shapes due, for example, to manufacturing. Thus, the regions illustrated in the figures are schematic in nature and their shapes are not intended to illustrate the actual shape of a region of a device and are not intended to limit the scope of the present disclosure.

Unless otherwise defined, all terms (comprising technical and scientific terms) used herein have the same meaning as commonly understood by one of ordinary skill in the art to which this disclosure belongs. It will be further understood that terms such as those defined in commonly used dictionaries should be construed to have meanings consistent with their meanings in the relevant art and/or the context of this specification, and will not be idealized or overly interpreted in a formal sense, unless expressly defined as such herein.

The above descriptions are merely specific embodiments of the present disclosure, but the protection scope of the present disclosure is not limited thereto. Any changes or substitutions that those skilled in the art can easily think of within the technical scope disclosed by the present disclosure, should be comprised within the protection scope of the present disclosure. Therefore, the protection scope of the present disclosure should be based on the protection scope of the claims.

1. A wiring substrate comprising:
a base substrate; and
a plurality of pad groups on the base substrate, each of the plurality of pad groups comprising at least two pads,
wherein two pads adjacent in a first direction or a second direction of the at least two pads are spaced apart,
wherein the first direction intersects with the second direction, and
wherein each of the at least two pads comprises a plurality of sides, the plurality of sides comprise at least one selected side and at least one non-selected side, any one pad is adjacent another pad along the first direction or the second direction, the selected side of the any one pad is a side among the plurality of sides facing the adjacent another pad, and a distance between the selected side of the any one pad facing the adjacent another pad and the selected side of the adjacent another pad facing the any one pad is greater than or equal to 30 μm and less than 100 μm.

2. The wiring substrate according to claim 1, further comprising:
an insulating layer on a side of the plurality of pad groups away from the base substrate,
wherein the insulating layer comprises a plurality of first openings, any one of the plurality of first openings corresponds to one of the plurality of pad groups.

3. The wiring substrate according to claim 2, wherein any one of the plurality of pad groups comprises two pads spaced apart along the first direction or the second direction, and
wherein an orthographic projection of the non-selected side of each of the two pads on the base substrate coincides with a part of a contour of an orthographic projection of a corresponding first opening on the base substrate.

4. The wiring substrate according to claim 2, wherein any one of the plurality of pad groups comprises four pads arranged in an array and spaced apart along the first direction and the second direction, the non-selected side of each of the four pads comprises at least one first non-selected side, and an orthographic projection of the first non-selected side on the base substrate coincides with a part of a contour of an orthographic projection of a corresponding first opening on the base substrate.

5. The wiring substrate according to claim 4, wherein the non-selected side of each pad further comprises a second non-selected side, and a minimum distance between an orthographic projection of the second non-selected side on the base substrate and the contour of the orthographic projection of the corresponding first opening on the base substrate is 30˜50 μm.

6. The wiring substrate according to claim 2, wherein any one of the plurality of pad groups comprises a plurality of pads spaced apart along the first direction or the second direction, a connection line sequentially connecting geometric centers of the plurality of pads in a clockwise direction forms a convex polygon, the non-selected side of each of the plurality of pads comprises at least one first non-selected side, and an orthographic projection of the first non-selected side on the base substrate coincides with a part of a contour of an orthographic projection of a corresponding first opening on the base substrate.

7. The wiring substrate according to claim 6, wherein the plurality of pads comprise a first type pad and a second type pad, the at least one selected side of the first type pad comprise a first selected side and a second selected side, an extending direction of the first selected side and an extending direction of the second selected side have an angle, the selected sides of the second type pad comprise a third selected side and a fourth selected side, and an extending direction of the third selected side is parallel to an extending direction of the fourth selected side.

8. The wiring substrate according to claim 7, wherein the first type pad is spaced apart from two second type pads in the first direction and the second direction respectively, and any pad adjacent to at least one of the second type pads is spaced apart from the second type pad along the first direction or the second direction.

9. The wiring substrate according to claim 7, wherein the non-selected sides of each first type pad further comprise a second non-selected side, and a minimum distance between an orthographic projection of the second non-selected side on the base substrate and the contour of the orthographic projection of the corresponding first opening on the base substrate is 30˜50 μm.

10. The wiring substrate according to claim 7, wherein the non-selected sides of each second type pad further comprise a third non-selected side, the second type pad is spaced apart from the first type pad along the first direction, a distance between the third non-selected side of the second type pad and the second selected side of the first type pad in the second direction is greater than zero and less than or equal to 30 μm, and the second selected side of the first type pad is a selected side of the first type pad facing the second type pad which is spaced apart from the first type pad along the second direction.

11. The wiring substrate according to claim 7, wherein the non-selected sides of each second type pad further comprise a third non-selected side, the second type pad is spaced apart from the first type pad along the second direction, a distance between the third non-selected side of the second type pad and the first selected side of the first type pad in the first direction is greater than zero and less than or equal to 30 μm, and the first selected side of the first type pad is a selected side of the first type pad facing the second type pad which is spaced apart from the first type pad along the first direction.

12. The wiring substrate according to claim 2, wherein no other layer is provided between a layer where the insulating layer is located and a layer where the plurality of pad groups are located.

13. An electronic device comprising the wiring substrate according to claim 1 and a plurality of electronic elements,
wherein the plurality of electronic elements are on a side of the plurality of pad groups away from the base substrate, any one of the plurality of electronic elements corresponds to one of the plurality of pad groups, each of the plurality of electronic elements comprises at least two pins, any one of the at least two pins corresponds to one of the at least two pads, and each pin of an electronic element is connected to a corresponding pad.

14. The electronic device according to claim 13, wherein a ratio of an area of a surface of a pin of each electronic element facing the corresponding pad to an area of a surface of the corresponding pad facing the pin is 0.4˜1.0.

15. The electronic device according to claim 13, wherein a first orthographic projection of a pin of each electronic element on the base substrate at least partially overlaps with a second orthographic projection of the corresponding pad on the base substrate, a region where the first orthographic projection and the second orthographic projection overlap comprises an overlapping region, a ratio of an area of the overlapping region to an area of the second orthographic projection is greater than or equal to 39%.

16. The electronic device according to claim 13, wherein an insulating layer is between the plurality of pad groups and the plurality of electronic elements, any one of the plurality of electronic elements corresponds to one of a plurality of first openings of the insulating layer, a third orthographic projection of each electronic element on the base substrate falls within a fourth orthographic projection of a corresponding first opening on the base substrate, and a distance between a contour of the third orthographic projection and a contour of the fourth orthographic projection is 20˜40 μm.

17. A method of manufacturing an electronic device, comprising:
providing a base substrate;
forming a plurality of pad groups on the base substrate, each of the plurality of pad groups comprising at least two pads; and
fixing a plurality of electronic elements on a side of the plurality of pad groups away from the base substrate,
wherein any one of the plurality of electronic elements corresponds to one of the plurality of pad groups, each of the plurality of electronic elements comprises at least two pins, any one of the at least two pins corresponds to one of the at least two pads, and each pin of an electronic element is connected to a corresponding pad.

18. The method according to claim 17,
wherein the forming a plurality of pad groups on the base substrate, comprises:
applying a conductive layer on the base substrate and patterning the conductive layer to form a plurality of signal lines; and
forming an insulating layer comprising a plurality of first openings on a side of the plurality of signal lines away from the base substrate, and forming the pads comprised by the pad groups by exposing a portion of each of the plurality of signal lines by the first openings,
wherein the fixing a plurality of electronic elements on a side of the plurality of pad groups away from the base substrate, comprises:
aligning each pin of an electronic element of the plurality of electronic elements with the corresponding pad, so that a first orthographic projection of each pin of the electronic element on the base substrate does not exceed a second orthographic projection of the corresponding pad on the base substrate; and
soldering each pin of the electronic element to the corresponding pad by a solder.

19. (canceled)

20. The method according to claim 18,
wherein each pad group comprises a plurality of pads spaced apart along a first direction or a second direction, the plurality of pads comprise a first type pad and a second type pad,
wherein the first type pad comprises a first selected side, a second selected side, a first non-selected side and a second non-selected side, an extending direction of the first selected side and an extending direction of the second selected side have a first angle, and an extending direction of the first non-selected side and an extending direction of the second non-selected side have a second angle,
wherein the second type pad comprises a third selected side, a fourth selected side, a first non-selected side and a third non-selected side, an extending direction of the third selected side is parallel to an extending direction of the fourth selected side, and an extending direction of the first non-selected side is parallel to an extending direction of the third non-selected side, and
wherein the aligning each pin of the electronic element with the corresponding pad, comprises:
aligning the first selected side and the second selected side of each first type pad with a first side and a second side of a corresponding pin respectively in a direction perpendicular to the base substrate, and making orthographic projections of the first non-selected side and the second non-selected side of each first type pad on the base substrate spaced apart from orthographic projections of a third side and a fourth side of the corresponding pin on the base substrate respectively by 20˜50 μm, and
aligning the third selected side and the fourth selected side of each second type pad with a fifth side and a sixth side of the corresponding pin respectively in the direction perpendicular to the base substrate, making an orthographic projection of the third non-selected side of each second type pad on the base substrate spaced apart from an orthographic projection of a seventh side of the corresponding pin on the base substrate by 0˜30 μm, and making an orthographic projection of the first non-selected side of each second type pad on the base substrate spaced apart from an orthographic projection of an eighth side of the corresponding pin on the base substrate by 20˜50 μm, the third non-selected side being closer to a center of a pad group than the first non-selected side.

21. (canceled)

22. The method according to claim 20, wherein each pad group comprises a central region and a plurality of corner regions surrounding the central region, each of the plurality of corner regions is provided with at least one first type pad and at least one second type pad,
wherein before aligning each pin of the electronic element with the corresponding pad, the method further comprises:
placing a mesh on the side of the plurality of pad groups away from the base substrate, the mesh comprising a plurality of second openings, any one of the plurality of second openings corresponding to one of the plurality of corner regions of the plurality of pad groups, an orthographic projection of each of the plurality of second openings on the base substrate partially overlapping with orthographic projections of the at least one first type pad and the at least one second type pad in a corresponding corner region on the base substrate;
printing soldering flux onto surfaces of the first type pad and the second type pad away from the base substrate through the second openings of the mesh; and
removing the mesh.
